(19) United States
(12) Patent Application Publication
(10) Pub. No.: US 2003/0080780 A1
(43) Pub. Date: May 1, 2003

(54) Output circuit

(75) Inventors: Takeo Okamoto, Hyogo (JP); Tadaaki Yamauchi, Hyogo (JP); Junko Matsumoto, Hyogo (JP); Kozo Ishida, Hyogo (JP); Hideki Yonetani, Hyogo (JP); Tsutomu Nagasawa, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/231,158

(22) Filed: Aug. 30, 2002

(30) Foreign Application Priority Data
Oct. 26, 2001 (JP) 2001-329039 (P)

(51) Int. Cl. H03K 19/094

(52) U.S. Cl. 326/83

(57) ABSTRACT

The output circuit has an output transistor adjusted in driving capability, using a negative voltage or changing a transistor size in accordance with the level of output power supply voltage. Particularly, by increasing the driving capability of a P-channel MOS transistor for pulling up the output node, an output signal can be generated at high speed while suppressing reduction of the driving capability of the P-channel MOS transistor even under a low output power supply voltage condition. An output circuit that can drive an output node with an optimum driving capability even if an output power supply voltage is changed, is provided.

### BACKGROUND OF THE INVENTION

1. Field of the Invention

The present invention relates to an output circuit, and particularly to a configuration of an output circuit for outputting a signal at high speed even under a low power supply voltage.

2. Description of the Background Art

FIG. 24 shows an example of a configuration of a final output stage of a conventional output circuit. In FIG. 24, the output circuit includes a P-channel MOS transistor (insulated gate field effect transistor) PQ that is connected between a power supply node and an output node ON and has a gate receiving an internal signal INP, and an N-channel MOS transistor NQ that is connected between output node ON and a ground node and has a gate receiving an internal signal INN.

Internal signals INP and INN are the same in logical level in a normal mode of operation and generated by an output drive control circuit not shown.

When internal signals INP and INN are at H level (logical high level), MOS transistor NQ is turned on, MOS transistor PQ is turned off and output node ON is discharged to ground voltage level.

When internal signals INP and INN are at L level (logical low level), MOS transistor PQ is turned on and MOS transistor NQ is turned off. In this state, output node ON is charged to an output power voltage VDDQ level by MOS transistor PQ and an output signal DQ attains H level.

When internal signal INP is at H level and internal signal INP is at L level, both of MOS transistors PQ and NQ are turned off and output node ON turns into a high impedance state.

In the output circuit, P-channel MOS transistor PQ and N-channel MOS transistor NQ each having a relatively high driving capability constitute an output drive stage for driving output node ON. These MOS transistors PQ and NQ drive the heavy load of output node ON, to which an external device or the like is connected, at high speed to transmit output signal DQ at high speed.

The H level of internal signal INP is the same as the voltage level of output power supply voltage VDDQ and the L level thereof is the same as a ground voltage level. The current driving capability of P-channel MOS transistor PQ is determined by a gate to source voltage Vgs of transistor PQ. Accordingly, when output power supply voltage VDDQ is relatively as high as, for example, 2.5V, the gate to source voltage Vgs of P-channel MOS transistor PQ assumes about 2.5V, and it becomes possible to charge output node ON at high speed.

If output power supply voltage VDDQ is lowered to, for example, 1.8V so as to reduce the power dissipation of an overall system and to transfer a signal at high speed, however, the gate to source voltage Vgs becomes 1.8V upon conduction of P-channel MOS transistor PQ, and the current driving capability of MOS transistor PQ is lowered compared with a case where power supply voltage VDDQ is 2.5V. In particular, an allowable value for output power supply voltage VDDQ is determined in a specification value and the allowable range of this output power supply voltage VDDQ is, for example, between 1.95V and 1.65V. Accordingly, if output power supply voltage VDDQ is lowered to the lower limit allowable value of 1.65V in this range, the current driving capability of P-channel MOS transistor PQ is disadvantageously reduced further, thereby making it impossible to drive output node ON at high speed to transmit output signal DQ at high speed.

Even if output power supply voltage VDDQ is lowered, such a countermeasure can be considered that the size of P-channel MOS transistor PQ (the ratio of a channel width W to a channel length L) is enlarged to increase the current driving capability of P-channel MOS transistor PQ. However, the power supply voltage of the system in which the semiconductor memory device is employed is relatively high in some cases, due to the compatibility of the system with a previous-generation system, the difference between the systems in interface, and others. If a semiconductor memory device having an output transistor of which size is enlarged is applied to this system, the capability of driving the output node becomes excessively high, with the result that ringing or the like may occur and data cannot be outputted at high speed.

Furthermore, it can be considered to decrease the absolute value of the threshold voltage of this P-channel MOS transistor PQ. However, if the absolute value of a threshold voltage is decreased, a leakage current (sub-threshold current) is increased in the turn off state of MOS transistor PQ and the current dissipation disadvantageously increases in a standby state.

Likewise, the gate to source voltage Vgs of N-channel MOS transistor NQ is decreased upon conduction of MOS transistor NQ. Accordingly, if the H level of internal signal INN applied to the gate of N-channel MOS transistor NQ is the same as output power supply VDDQ level, the current driving capability of N-channel MOS transistor NQ is also lowered and the output node cannot be discharged at high speed.

The lowering of the output power supply voltage as described above is particularly significant in a semiconductor memory device. If the operating speed of the output circuit is decreased under a lower power supply voltage, the operating speed of the semiconductor memory device is limited by the operating speed of the output circuit and the semiconductor memory device cannot be operated at high speed, so that a processing system which performs a high-speed processing at a lower power supply voltage cannot be constructed.

### SUMMARY OF THE INVENTION

It is an object of the present invention to provide an output circuit which can output a signal at high speed even under a low power supply voltage.

It is another object of the present invention to provide a data output circuit, suited to a semiconductor memory device, operable at high speed even under a low power supply voltage.

According to the first aspect of the present invention, an output circuit includes: a first output transistor of a first conductivity type, connected between an output node and a power supply node supplying an output power supply, and made selectively conductive in accordance with an internal signal; and a second transistor of a second conductivity type, connected between the power supply node and the output node, and made conductive in a common phase with the first transistor in accordance with the internal signal.

According to the second aspect of the present invention, an output circuit includes: a first transistor of a first conductivity type, connected between an output power supply node and an output node; a second transistor of the first conductivity type, connected between the output power supply node and the output node; a first drive circuit selectively driving the first transistor to a conductive state in accordance with an internal signal; and a second drive circuit selectively activated in accordance with an operation mode instruction signal, and selectively driving the second transistor to the conductive state in accordance with the internal signal when activated. The second drive circuit includes: a first gate circuit generating a first control signal at a voltage level of the output power supply node in accordance with the operation mode instruction signal; a second gate circuit generating a second control signal at a level of an external power supply voltage in accordance with the operation mode instruction signal; a third transistor driving a gate electrode of the second transistor to the voltage level of the output power supply voltage node in accordance with the internal signal; a fourth transistor selectively made conductive in accordance with the first control signal, and driving the gate electrode of the second transistor to an output power supply voltage level of the output power supply node when made conductive; and fifth and sixth transistors connected in series between the gate electrode of the second transistor and a reference node supplying a reference voltage different in polarity from the output power supply voltage. A gate of the fifth transistor receives the second control signal, and a gate electrode of the sixth transistor receives the internal signal.

According to the third aspect of the present invention, an output circuit includes a first output stage having a driving capability changeable fixedly in accordance with an operation mode specifying a level of a power supply voltage, and driving an output node to a voltage level of an output power supply node in accordance with an internal signal with the set driving capability.

According to the fourth aspect of the present invention, an output circuit includes: an output drive circuit generating a signal changing between a negative voltage and an output power supply voltage in accordance with an internal signal; and a first transistor driving an output node to a level of the output power supply voltage in accordance with an output signal of the output drive circuit.

According to the fifth aspect of the present invention, an output circuit is constituted to be able to change a bit width of output data, wherein the power supply node of a data output circuit which is not used is connected to a power supply line transmitting a voltage different from the voltage of an output power supply line transmitting an output power supply voltage.

Transistors of different conductivity types are arranged in parallel on a section of driving the output node. Thus, compared with a case of arranging transistors of the same conductivity type in parallel, a driving capability of one transistor can be made higher than the driving capability of other transistor with the same occupying area, to increase the output node driving capability while suppressing the increase of the circuit area.

By forming an output transistor in a well region, in particular, it is possible to arrange transistors of different conductivity types in parallel. In addition, by biasing the substrate region of this output transistor to the level of the output power supply voltage, it is possible to utilize a parasitic bipolar transistor when driving the output node, and thus, the output node can be driven at higher speed.

Moreover, by arranging output transistors in parallel and selectively activating one transistor in accordance with the operation mode instruction signal, it is possible to adjust the output node driving capability in accordance with an operation mode. In this case, by changing the voltage level of the operation mode instruction signal to the external power supply voltage level and applying the changed voltage level to one of the transistors, connected in series, for driving the output transistor, it is possible to drive the output transistor at high speed. In addition, the serially connected transistors can mitigate the drain electric field of a transistor driving the output transistor, to prevent generation of hot carriers.

Further, by adjusting the driving capability of a first output stage driving the output node to the level of the power supply voltage in accordance with the level of the power supply voltage, it is possible to adjust the driving speed of the output node depending on the power supply voltage, and thus, the output node can be driven at high speed even under a low power supply voltage.

Further, by enlarging the amplitude of the signal driving these output transistors, it becomes possible to increase the gate to source voltage upon conduction even under the lower power supply voltage. Accordingly, it is possible to enhance driving capability to drive the output node at high speed.

Moreover, with the configuration in which the bit width of the output data can be changed, by fixing the potential of the power supply node of the data output circuit which is not used, to a voltage different from the data output power supply voltage, it is possible to stabilize the voltage of the power supply node of the unused data output circuit and to prevent the power supply noise of the unused data output circuit from adversely influencing the operation of other circuitry.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram showing an overall configuration of a semiconductor memory device according to the present invention;

FIG. 2 is a schematic diagram showing a configuration of an output circuit according to a first embodiment of the present invention;

FIG. 3 is a schematic diagram showing a configuration of a pull-up level conversion circuit shown in FIG. 2;

FIG. 4 shows an example of a configuration of a pull-down level conversion circuit shown in FIG. 2;

FIG. 5 is a schematic diagram showing a configuration of an output circuit according to a second embodiment of the present invention;

FIG. 6 is a signal waveform diagram representing an operation of the output circuit shown in FIG. 5;

FIG. 7 is a schematic diagram showing a configuration of an output circuit according to a third embodiment of the present invention;

FIG. 8 is a signal waveform diagram representing an operation of the output circuit shown in FIG. 7;

FIG. 9 is a schematic diagram showing a modification of the third embodiment;

FIG. 10 is a schematic diagram showing a configuration of an output circuit according to a fourth embodiment of the present invention;

FIG. 11A is a diagram showing a configuration of an output circuit according to a fifth embodiment of the present invention, and FIG. 11B a signal waveform diagram representing an operation of the output circuit shown in FIG. 11A;

FIG. 12 is a schematic diagram showing a configuration of an output control circuit according to a sixth embodiment of the present invention;

FIG. 13 is a schematic diagram showing a configuration of an output circuit according to a seventh embodiment of the present invention;

FIG. 14 is a diagram showing a modification of the seventh embodiment;

FIG. 15 is a diagram showing a configuration of an output circuit according to a eighth embodiment of the present invention;

FIG. 16 is a schematic diagram showing a cross-sectional structure of a pull-up N-channel MOS transistor shown in FIG. 15;

FIG. 17 is a diagram showing a configuration of an output circuit according to a ninth embodiment of the present invention;

FIG. 18 is a diagram showing a configuration a main portion of an output circuit according to a tenth embodiment of the present invention;

FIG. 19 is a diagram showing a configuration of an output circuit according to an eleventh embodiment of the present invention;

FIG. 20 is a diagram showing a configuration of an output circuit according to a twelfth embodiment of the present invention;

FIG. 21 is a schematic diagram showing an arrangement of power supplies and output buffer circuits of a semiconductor memory device according to a thirteenth embodiment of the present invention;

FIG. 22 specifically shows power supply arrangement of an output circuit according to the thirteenth embodiment of the present invention;

FIG. 23 is a schematic diagram showing a configuration a main portion of an output circuit according to a fourteenth embodiment of the present invention; and

FIG. 24 shows an example of a configuration of a conventional output buffer circuit.

### DESCRIPTION OF THE PREFERRED EMBODIMENTS

[Overall Configuration]

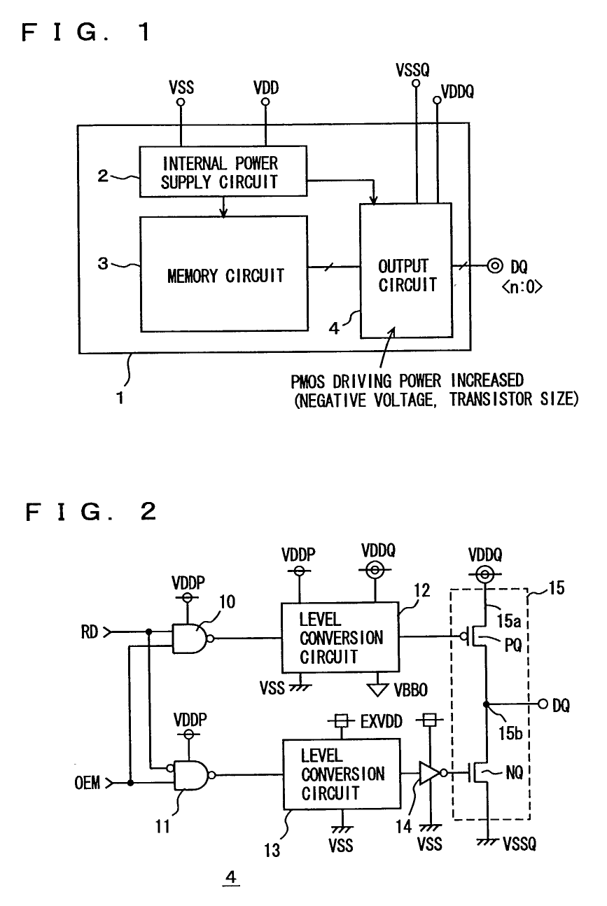

FIG. 1 shows an overall configuration of a semiconductor memory device which includes an output circuit according to the present invention. In FIG. 1, a semiconductor memory device 1 includes an internal power supply circuit 2 that generates various internal voltages including an internal power supply voltage in accordance with external power supply voltages EXVDD and VSS, a memory circuit 3 that receives the various voltages (internal power supply voltage and internal voltages) from internal power supply circuit 2, performs selection of a memory cell, and writing and reading of data, and an output circuit 4 that outputs data read from memory circuit 3 externally.

Memory circuit 3 includes a plurality of memory cells for storing information, a memory select circuit for selecting a memory cell, an internal write/read circuit for writing and reading data to and from the selected memory cell, and a peripheral control circuit for controlling these operations.

Output circuit 4 outputs data bits DQ <n:0> when active. Output power supply voltages VDDQ and VSSQ, separate from external power supply voltages EXVDD and VSS, are supplied to output circuit 4. The output circuit 4 includes a circuit which uses the internal voltages from internal power supply circuit 2 in order to process the data read from memory circuit 3. With dedicated output power supply voltages VDDQ and VSSQ supplied to output circuit 4, output circuit 4 can be stably supplied with a power supply voltage while data is outputted, and the fluctuation of the power supply voltage can be prevented from adversely influencing the operation of the internal circuit when data is outputted.

According to the present invention, the driving capability of output circuit 4 is increased using a configuration to be described later such as the use of a negative voltage and/or the change of transistor size, to generate output data DQ<n:0> at high speed even when the output power supply voltage is lowered.

[First Embodiment]

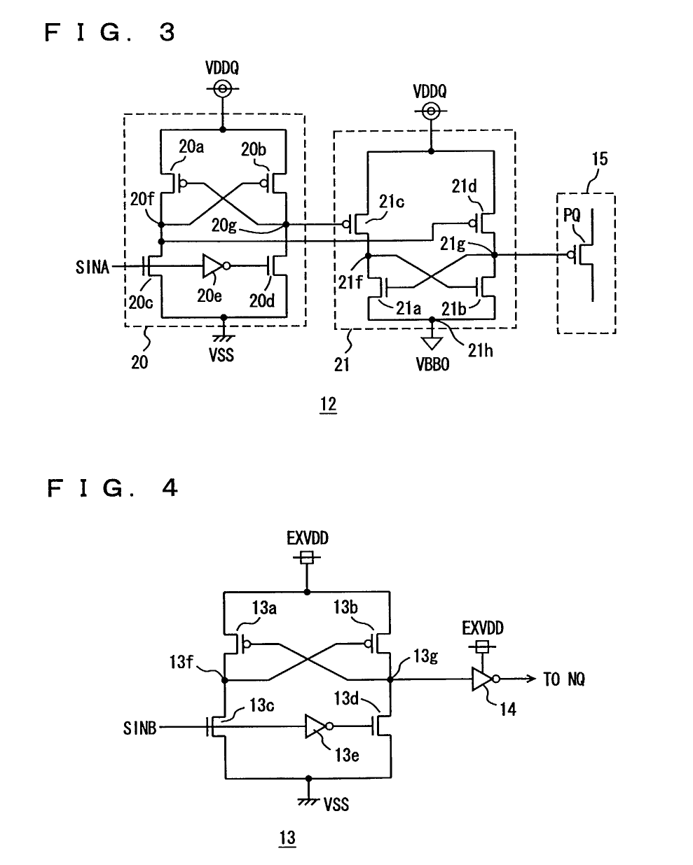

FIG. 2 is a schematic diagram showing a configuration of an output circuit 4 according to a first embodiment of the present invention. In FIG. 2, output circuit 4 includes a NAND circuit 10 that receives internal read data RD read from a memory circuit 3 and an output permission signal OEM from an output control circuit included in memory circuit 3, a gate circuit 11 that receives internal read data RD and output permission signal OEM, a level conversion circuit 12 that converts the output signal of NAND circuit 10 into a signal changing between an output power supply voltage VDDQ and a negative voltage VBB0, a level conversion circuit 13 that converts the output signal of gate circuit 11 into a signal changing between an external power supply voltage EXVDD and a ground voltage VSS, an inverter 14 that receives the output signal of level conversion circuit 13, and a buffer circuit 15 that generates an output data DQ in accordance with the output signals of level conversion circuit 12 and inverter 14.

FIG. 2 shows the configuration of the section of output circuit 4 which outputs 1-bit data DQ. The configuration shown in FIG. 2 is arranged in correspondence to each respective output data bit.

NAND circuit 10 receives a peripheral power supply voltage VDDP from internal power supply circuit 2 shown in FIG. 1 as one operating power supply voltage, and outputs an L level signal when both internal read data RD and output permission signal OEM are at H level. This NAND circuit 10 outputs an H level signal at a peripheral power supply voltage VDDP level when one of internal read data RD and output read data RD is at H level.

Gate circuit 11 receives peripheral power supply voltage VDDP as one operating power supply voltage, and outputs the L level signal when internal read data RD is at L level and output permission signal OEM is at H level. This gate circuit 11 outputs H level signal at peripheral power supply voltage VDDP level when output permission signal OEM is at L level or internal read data RD is at H level.

Level conversion circuit 12 receives peripheral power supply voltage VDDP, ground voltage VSS, output power supply voltage VDDQ and negative voltage VBB0 as operating power supply voltages, and converts a signal having an amplitude of VDDP from NAND circuit 10 into a signal having an amplitude of VDDQ−|VBB0|.

Level conversion circuit 13 receives external power supply voltage EXVDD and ground voltage VSS, and converts a signal having an amplitude of VDDP level from gate circuit 11 into a signal having an amplitude of EXVDD.

Inverter 14 receives external power supply voltage EXVDD and ground voltage VSS as operating power supply voltages, and inverts the output signal of level conversion circuit 13.

Output buffer circuit 15 includes a P-channel MOS transistor PQ which turns conductive when the output signal of level conversion circuit 12 is at L level to transmit output power supply voltage VDDQ on an output power supply node 15a to an output node 15b, and an N-channel MOS transistor NQ which turns conductive when the output signal of inverter 14 is at H level to drive output node 15b to an output ground voltage VSSQ level. Level conversion circuit 12 generates an L level signal of a negative voltage VBB0 level onto the gate of P-channel MOS transistor PQ included in output buffer circuit 15. A gate to source voltage Vgs of P-channel MOS transistor PQ upon conduction thereof can be set at VBB0−VDDQ and increased by as much as negative voltage VBB0 compared with a conventional case of applying the L level signal of a ground voltage. Thus, the current driving capability of P-channel MOS transistor PQ can be enhanced. Therefore, even if the specification value of output power supply voltage VDDQ is, for example, 1.8V and output power supply voltage VDDQ is lowered to a lower limit allowable value of 1.65V, P-channel MOS transistor PQ can supply a current to output node 15b with a sufficiently high driving capability.

If P-channel MOS transistor PQ is provided with a sufficient current driving capability under the condition of output power supply voltage VDDQ of, for example, 2.5V, the voltage level of negative voltage VBB0 may be set at voltage level at which the voltage drop amount of 0.7 V (2.5 minus 1.8 V) can be compensated for in terms of current driving power when output power supply voltage VDDQ is lowered to 1.8V. This voltage level can be obtained based on the square characteristic in a saturated region of a drain current of an MOS transistor.

N-channel MOS transistor NQ receives external power supply voltage EXVDD at a gate thereof when conductive. This external power supply voltage EXVDD is higher than output power supply voltage VDDQ if the voltage VDDQ is, for example, 1.8V. Thus, it is possible to increase the gate to source voltage, upon conduction, of N-channel MOS transistor NQ and to discharge output node 15b at high speed.

As shown in FIG. 2, therefore, if level conversion circuit 12 generates a signal at negative voltage VBB0 level as an L level signal, in output buffer circuit 15, the current driving capability of P-channel MOS transistor PQ for pulling up output node 15b can have the current driving power increased and drive output node 15b at high speed even if output power supply voltage VDDQ is lowered.

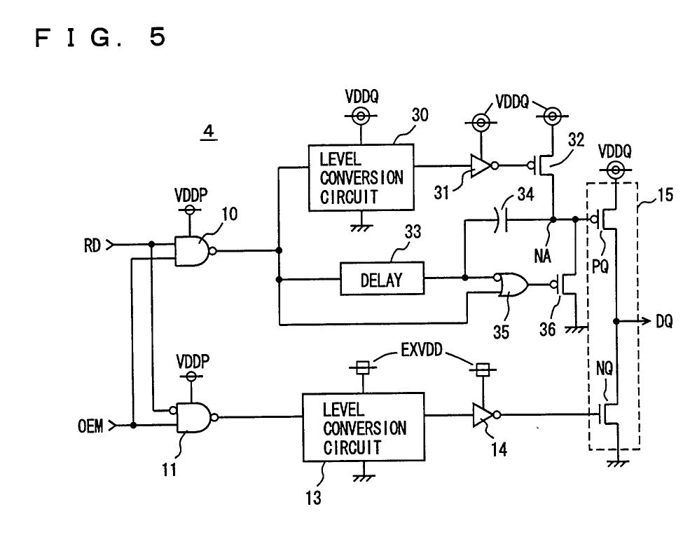

FIG. 3 shows an example of a configuration of level conversion circuit 12 shown in FIG. 2. In FIG. 3, level conversion circuit 12 includes a first level converter 20 which converts an output signal SINA of NAND circuit 10 shown in FIG. 2 into a signal having an amplitude of output power supply voltage VDDQ level, and a second level converter 21 which converts the output signal of first level converter 20 into a signal having an amplitude of VDDQ−VBB0.

First level converter 20 includes cross-coupled P-channel MOS transistors 20a and 20b, an N-channel MOS transistor 20c which is connected between an internal node 20f and a ground node and has a gate receiving output signal SINA, and an NAND circuit 20d which is connected between an internal node 20g and the ground node and has a gate receiving signal SINA through an inverter 20e. The operating power supply voltage of inverter 20e is peripheral power supply voltage VDDP.

P-channel MOS transistor 20a is connected between an output power supply node and an internal node 20f and has a gate connected to internal node 20g. P-channel MOS transistor 20b is connected between the output power supply node and internal node 20e and has a gate connected to internal node 20f.

In first level converter 20, when the signal SINA is at H level, MOS transistor 20c is turned on and MOS transistor 20b is turned off. In this state, internal node 20f is driven to ground voltage level through MOS transistor 20c, MOS transistor 20b is turned on and the voltage level of internal node 20g attains output power supply VDDQ level. When internal node 20g attains H level, MOS transistor 20a is turned off, internal node 20f finally attains ground voltage VSS level and internal node 20g finally attains output power supply voltage VDDQ level.

In contrast, when the signal SINA is at L level, MOS transistor 20c is turned off and MOS transistor 20b is turned on. In this state, internal node 20g is driven to ground voltage VSS level through MOS transistor 20d and internal node 20f is charged by MOS transistor 20a to the output power supply VDDQ level. When internal node 20f attains output power supply voltage VDDQ level, MOS transistor 20b is fully turned off.

Accordingly, this first level converter 20 converts the signal SINA at peripheral power supply voltage VDDP level into a signal at output power supply voltage VDDQ level. First level converter 20 simply converts the signal amplitude and does not invert the logical level of an input signal.

Second level converter 21 includes cross-coupled N-channel MOS transistors 21a and 21b, a P-channel MOS transistor 21c which is connected between the output power supply node and an internal node 2 if and has a gate connected to internal node 20g of first level converter 20, and a P-channel MOS transistor 2 id which is connected between the output power supply node and internal node 21g and has a gate connected to internal node 20f of first level converter 20.

MOS transistor 21a is connected between internal node 2 if and a negative voltage node 21h and has a gate connected to internal node 21g. MOS transistor 21b is connected between internal node 21g and negative voltage 21h and has a gate connected to internal node 21f. Negative voltage VBB0 is applied to negative voltage node 21h.

It is assumed that internal nodes 20f and 20g of first level converter 20 are at output power supply voltage VDDQ level and ground voltage VSS level, respectively. In this state, MOS transistor 21c is turned on, MOS transistor 21d is turned off and internal node 21f is charged by MOS transistor 21c to the output power supply voltage VDDQ level in second level converter 21. MOS transistor 21b turns conductive in accordance with the voltage increase of internal node 21f and internal node 21g is driven toward negative voltage VBB0 level. When internal node 21g is driven to the negative voltage VBB0 level, MOS transistor 21a is turned off. In this state, therefore, a signal at negative voltage VBB0 level is outputted from internal node 21g and applied to the gate of P-channel MOS transistor PQ of output buffer circuit 15.

Next, it is considered that internal node 20f is at a ground voltage VSS level and internal node 20e is at an output power supply voltage VDDQ level in first level converter 20. In this state, MOS transistor 21c is turned off, MOS transistor 21d is turned on and internal node 21g is charged to the output power supply voltage VDDQ level through MOS transistor 21d. MOS transistor 21a turns conductive in accordance with the voltage increase of internal node 21g and internal node 21f is driven toward negative voltage VBB0 level. When internal node 21f reaches at the negative voltage VBB0 level, MOS transistor 21b is turned off. Accordingly, a signal at the output power supply voltage VDDQ level is outputted from internal node 21g of second level converter 21. This level converter 21 simply converts the amplitude of the output signal of first level converter 20 and does not change the logical level of the input signal.

Therefore, with the configuration of level conversion circuit 12 shown in FIG. 3, when output signal SINA of NAND circuit 10 shown in FIG. 2 is at ground voltage VSS level, a signal at negative voltage VBB0 level is generated and applied to the gate of MOS transistor PQ of output buffer circuit 5. When output signal SINA of NAND circuit 10 is at peripheral power supply voltage VDDP level, internal node 20g attains output power supply voltage VDDQ level and the voltage level of internal node 21g of second level converter 21 attains output power supply voltage VDDQ level, accordingly. Therefore, level conversion circuit 12 converts the L level of output signal SINA of NAND circuit 10 from ground voltage level to negative voltage level and the H level thereof into output power supply voltage VDDQ level while maintaining the logical level of output signal SINA of NAND circuit 10.

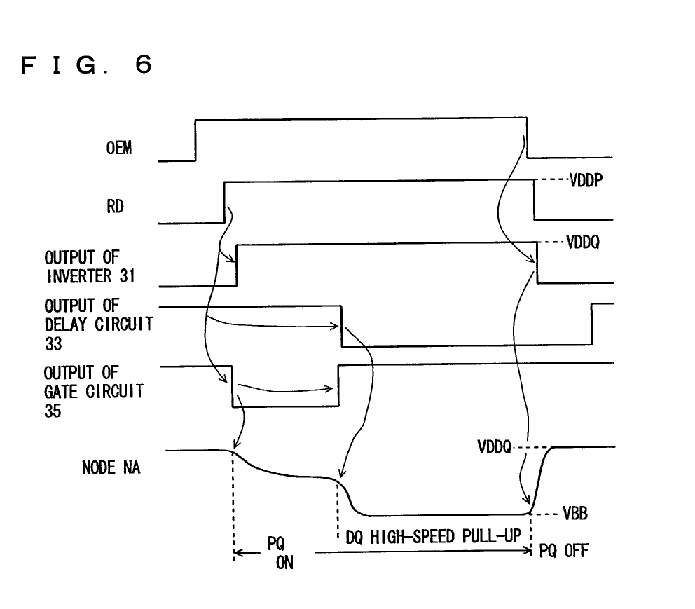

FIG. 4 shows an example of the configuration of level conversion circuit 13 shown in FIG. 2. In FIG. 4, level conversion circuit 13 includes cross-coupled P-channel MOS transistors 13a and 13b, an N-channel MOS transistor 13c which is connected between an internal node 13f and a ground node and has a gate receiving an output signal SINB of gate circuit 11 shown in FIG. 2, and an N-channel MOS transistor 13d which is connected between an internal node 13g and a the ground node and has a gate receiving the signal SINB through an inverter 13e. Inverter 13e receives peripheral power supply voltage VDDP as one operating power supply voltage.

MOS transistor 13a is connected between an external power supply node and internal node 13f and has a gate connected to internal node 13g. MOS transistor 13b is connected between the external power supply node and internal node 13g and has a gate connected to internal node 13f. The output signal of internal node 13g is applied through inverter 14 to the gate of N-channel MOS transistor NQ of the output buffer circuit.

The level conversion operation of level conversion circuit 13 is the same as that of first level converter 20 shown in FIG. 3. That is, when output signal SINB of gate circuit 11 shown in FIG. 2 is at peripheral power supply voltage VDDP level, MOS transistor 13c is turned on, MOS transistor 13d is turned off and internal node 13g is charged by MOS transistor 13b to external power supply voltage EXVDD level. On the other hand, when the signal SINB is at ground voltage VSS level, MOS transistor 13c is turned off, MOS transistor 13d is turned on and internal node 13g is discharged by MOS transistor 13d to ground voltage VSS level. The signal at internal node 13g is inverted by inverter 14 and applied to the gate of N-channel MOS transistor NQ included in output buffer circuit 15.

The level conversion circuit shown in FIG. 4 converts the signal SINB having an amplitude of peripheral power supply voltage VDDP level into a signal having an amplitude of external power supply voltage EXVDD level while maintaining the logical level of the signal SINB. By driving N-channel MOS transistor NQ with external power supply voltage EXVDD, the output node can be driven to ground voltage level at high speed if external power supply voltage EXVDD is at e.g., 2.5V, higher than output power supply voltage VDDQ. This external power supply voltage EXVDD may be equal in voltage level as output power supply voltage VDDQ. By using external power supply voltage EXVDD for pulling down the output node and using the output power supply voltage VDDQ for pulling up the output node, even if the output circuit is provided for each respective bit of output data and a large number of output nodes are charged and discharged, a signal bit to be driven to H level can be stably driven to the H level at high speed and reliably while suppressing the fluctuation of the output power supply voltage VDDQ.

Negative voltage VBB0 is generated from a negative voltage generation circuit included in internal power supply node 2 shown in FIG. 1. A pumping circuit which makes use of the charge pumping operation of a capacitor to generate the negative voltage VBB0 from external power supply voltage EXVDD can be used for the negative voltage generation circuit. The voltage level of negative voltage VBB0 is set at an appropriate level depending on the driving capability required for P-channel MOS transistor PQ for pulling up the output node.

As described above, according to the first embodiment, the signal at negative voltage level instead of the signal at ground voltage level is applied to the gate of output node pull-up MOS transistor in the output circuit. Even if output power supply voltage VDDQ is lowered, it is possible to set the gate to source voltage upon conduction of the output pull-up P-channel MOS transistor of the output buffer circuit to be sufficiently high. Thus, the output node can be driven at high speed under a low power supply voltage. In the semiconductor memory device, in particular, the output circuit outputting data at high speed can be achieved even under a low power supply voltage.

[Second Embodiment]

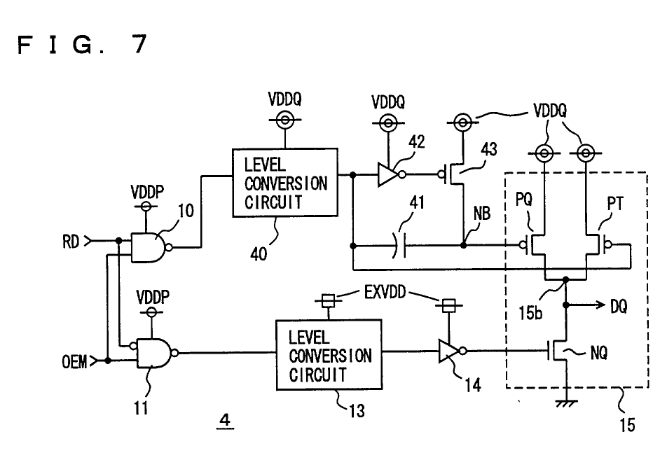

FIG. 5 is a schematic diagram of an output circuit according to a second embodiment of the present invention. In FIG. 5, a circuit for driving a pull-down N-channel MOS transistor NQ of an output buffer circuit 15 is the same in configuration as that shown in FIG. 2. Therefore, corresponding components are denoted by the same reference numerals as those in FIG. 2, and a detailed description thereof will not be repeated.

In an output circuit 4 shown in FIG. 5, a charge pumping operation (capacitive coupling) of a capacitor is utilized for driving the gate of a pull-up P-channel MOS transistor PQ included in an output buffer circuit 15 to a negative voltage level.

Specifically, in FIG. 5, output circuit 4 includes a level conversion circuit 30 which converts an amplitude of an output signal of a NAND circuit 10 to an output power supply voltage VDDQ level, an inverter 31 which inverts an output signal of level conversion circuit 30, and a P-channel MOS transistor 32 which is rendered conductive when the output signal of inverter 31 is at L level and drives an internal node NA to output power supply voltage VDDQ level when conductive.

Level conversion circuit 30 has the same configuration as that of a first level converter 20 shown in FIG. 3.

Output circuit 4 also includes a delay circuit 33 which delays the output signal of NAND circuit 10 by a predetermined time period, a capacitance element 34 which extracts the charges of internal node NA in response to the rise of the output signal of delay circuit 33, a gate circuit 35 which receives the output signal of delay circuit 33 and the output signal of NAND circuit 10, and a P-channel MOS transistor 36 which turns conductive when the output signal of gate circuit 35 is at L level and discharges internal node NA to ground voltage level when rendered conductive. The operating power supply voltages of delay circuit 33 and gate circuit 35 may be at peripheral power supply voltage level, external power supply voltage EXVDD, or output power supply voltage VDDQ.

Gate circuit 35 outputs an H level signal when the output signal of delay circuit 33 is at L level or the output signal of NAND circuit 10 is at H level.

FIG. 6 is a signal waveform diagram representing an operation of output circuit 4 shown in FIG. 5 in a case when output data DQ is pulled up. The operation of output circuit 4 in a case when the output node of output circuit 4 shown in FIG. 5 is pulled up will be described with reference to FIG. 6.

In a standby state, an output permission signal OEM is at L level, the output signal of NAND circuit 10 is at H level or the peripheral power supply voltage VDDP level and gate circuit 35 outputs a signal at H level or at the operating power supply voltage level. MOS transistor 36 is, therefore, maintained non-conductive.

On the other hand, when level conversion circuit 30 outputs a signal of H level or the output power supply voltage VDDQ level and inverter 31 outputs an L level signal accordingly, P-channel MOS transistor 32 is turned on, node NA is connected to the output power supply node and precharged to the output power supply voltage VDDQ level.

When output permission signal OEM attains H level for data reading and internal read data RD read from memory circuit 3 rises to H level, the output signal of NAND circuit 10 attains L level. Since the output signal of delay circuit 33 is at H level at this moment, the output signal of gate circuit 35 attains L level, MOS transistor 36 is turned on and node NA is discharged to ground voltage level. The voltage level of node NA is lowered to the voltage level of |Vthp| at the lowest. Here, Vthp indicates the threshold voltage of MOS transistor 36.

On the other hand, the output signal of level conversion circuit 30 is at L level, the output signal of inverter 31 is at H level or the output power supply voltage VDDQ level and MOS transistor 32 is turned off. Therefore, in accordance with the drop of the voltage of node NA, pull-up P-channel MOS transistor PQ of output buffer circuit 5 is turned on to raise the voltage level of the output node. In this state, however, the voltage level of node NA is |Vthp| level, the gate to source voltage of MOS transistor PQ is |Vthp |−VDDQ level. Therefore, MOS transistor PQ is in a relatively weak on state and MOS transistor PQ charges output node 15b at a relatively low current driving power.

When the delay time provided by delay circuit 33 passes, the output signal of delay circuit 33 attains L level, the output signal of gate circuit 35 attains H level and MOS transistor 36 is turned off. At this time, since both MOS transistors 32 and 36 are turned off, node NA is in an electrically floating state, and capacitance element 34 extracts charges from node NA in accordance with the lowering of the voltage level of the output signal of delay circuit 33 and lowers the voltage level of node NA to the negative voltage VBB level. When the node NA is driven to the negative voltage VBB level, the current driving capability of pull-up P-channel MOS transistor PQ in output circuit 5 is increased to drive output node 15b at higher speed to raise output data DQ to H level at high speed. Even if node NA is lowered to negative voltage VBB level, the gate voltage of MOS transistor 36 is at H level sufficiently higher than the voltage level of node NA, and MOS transistor 36 is reliably maintained non-conductive.

When data read operation is completed, output permission signal OEM falls to L level, the output signal of NAND circuit 10 attains H level and the output signal of inverter 31 attains L level. Accordingly, MOS transistor 32 is turned on to drive node NA to the output power supply voltage level. At this time, when the output signal of NAND circuit 10 rises to H level, the output signal of gate circuit 35 attains H level irrespectively of the logical level of the output signal of delay circuit 33, thereby maintaining MOS transistor 36 non-conductive.

When the output signal of delay circuit 33 rises to H level, internal node NA is already precharged to the output power supply voltage VDDQ level by MOS transistor 32. Thus, even if capacitance element 34 performs a charge pumping operation, the internal node NA is maintained at the output power supply voltage VDDQ level.

As shown in FIG. 5, after the internal node NA is driven to the ground voltage level (to be exact, the voltage level of the absolute value of the threshold voltage of MOS transistor 36), the charges of internal node NA are extracted by capacitance element 34 in accordance with the output signal of delay circuit 33 while making use of the charge pumping operation (capacitive coupling) of capacitance element 34. Thus, the internal node NA can be driven to a negative voltage level at high speed.

The voltage level of negative voltage VBB is determined by the ratio of the capacitance value of capacitance element 34 to that of the parasitic capacitance of internal node NA and the amplitude of the output signal of delay circuit 33.

According to the configuration of the output circuit shown in FIG. 5, the gate voltage of pull-up P-channel MOS transistor PQ is driven in two steps. Thus, large charging current is prevented from being rapidly driven into the output node to cause ringing, and output data DQ can be driven to output power supply voltage VDDQ level at high speed stably.

In addition, according to the configuration shown in FIG. 5, no negative voltage generation circuit is used but only the charge pumping operation of capacitance element 34 is utilized. Thus, a negative voltage generation circuit can be dispensed with, to decrease an area occupied by the circuit and to decrease current consumption accordingly.

It is noted that when the output node of this output circuit is driven to L level, the output signal of NAND circuit 10 is at H level the same as the level in a standby state, and internal node NA is maintained at the output power supply voltage VDDQ level.

As described above, according to the second embodiment of the present invention, the gate of the output node pull-up P-channel MOS transistor is driven to a negative voltage level making use of the charge pumping operation of the capacitance element. Thus, a negative voltage generation circuit can be dispensed with, to save current consumption in and an area occupied by the negative voltage generation circuit.

According to the configuration of the output circuit shown in FIG. 5, capacitance element 34 is only required to perform a charge extracting operation after MOS transistor 36 is turned off. Therefore, the output circuit may be constituted such that capacitance element 34 performs a charge extracting operation in accordance with the inverted signal of the output signal of gate circuit 35.

[Third Embodiment]

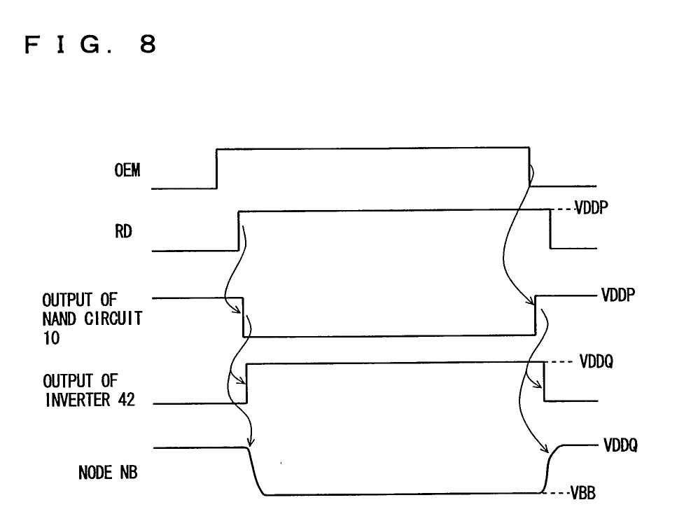

FIG. 7 is a schematic diagram showing a configuration of an output circuit of a third embodiment according to the present invention. In an output circuit 4 shown in FIG. 7, the configuration of the section for driving an N-channel MOS transistor NQ included in an output buffer circuit 5 is the same as that of the output circuit shown in FIG. 2. Therefore, corresponding components are denoted by the same reference numerals as those in FIG. 2, and a detailed description thereof will not be repeated.

In output circuit 4 shown in FIG. 7, a capacitance element 41 is provided between the gate of a pull-up P-channel MOS transistor PQ in output buffer circuit 5 and an output of a NAND circuit 10. To achieve the charge pumping operation of capacitance element 41, output circuit 4 further includes a level conversion circuit 40 which converts the amplitude of the output signal of NAND circuit 10 to an amplitude of an output power supply voltage VDDQ level, an inverter 42 which receives the output signal of level conversion circuit 40, and a P-channel MOS transistor 43 which turns conductive when the output signal of inverter 42 is at L level and charges a node NB to output power supply voltage VDDQ level when conductive.

In output buffer circuit 5, a P-channel MOS transistor PT for holding a voltage is provided in parallel to pull-up P-channel MOS transistor PQ. The output signal of level conversion circuit 40 is applied to the gate of P-channel MOS transistor PT.

Level conversion circuit 40 has the same configuration as that of a first level converter 20 shown in FIG. 3. Level conversion circuit 40 maintains the logical level of an output signal of NAND circuit 10, but drives the H level of the output signal of NAND circuit 10 from a peripheral power supply voltage VDDP level to an output power supply voltage VDDQ level.

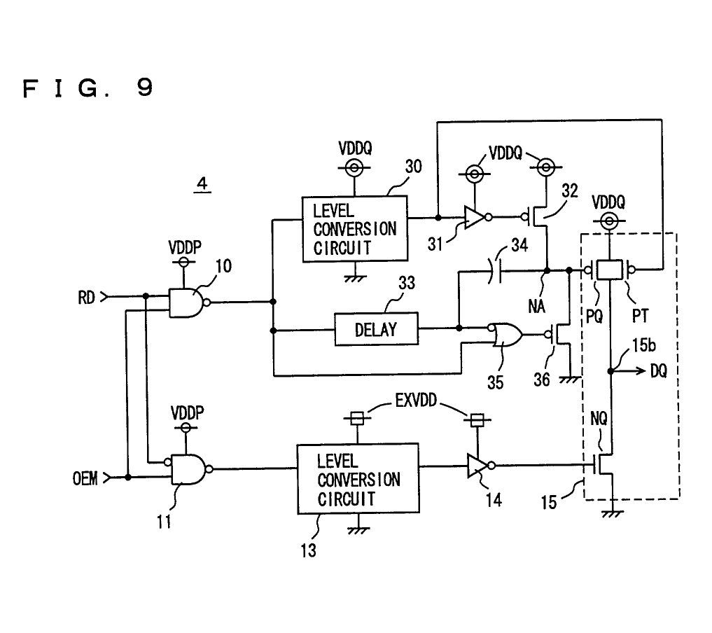

FIG. 8 is a waveform diagram representing an operation of output circuit 4 shown in FIG. 7 in a case when the output node of output circuit 4 is pulled up. The operation of output circuit 4 shown in FIG. 7 will now be described with reference to FIG. 8.

In a standby state, output permission signal OEM is at L level, the output signal of NAND circuit 10 is at H level and accordingly, the output signal of inverter 42 is at L level. Therefore, an internal node NB is precharged to and maintained at the output power supply voltage VDDQ level by MOS transistor 43. MOS transistor PQ is maintained off, accordingly. In addition, the output signal of level conversion circuit 40 is at the output power supply voltage VDDQ level, and P-channel MOS transistor PT of output buffer circuit 5 is maintained off, as well.

The output signal of NAND circuit 11 is at H level, the output signal of inverter 14 is at L level and MOS transistor NQ is, therefore, maintained off, as well. In the following description, the operation of output circuit 4 for pulling up the data output node will be described and the operation of pull-down MOS transistor NQ will not be described.

When data is outputted, output permission signal OEM attains H level and then internal read data RD from memory circuit 3 attains H level or the peripheral power supply voltage VDDP level. When internal read data RD rises to H level (peripheral power supply voltage VDDP level), the output signal of NAND circuit 10 attains L level and the output signal of level conversion circuit 40 attains a ground voltage level, accordingly. The output signal of inverter 42 rises to the output power supply voltage VDDQ level, P-channel MOS transistor 43 is turned off to stop the precharge operation for precharging internal node NB. In addition, when internal node NB turns into a floating state at this time, capacitance element 41 performs a charge extracting operation in accordance with the fall of the output signal of level conversion circuit 40 to lower the voltage level of internal node NB to a negative voltage VBB level. The degree of the decrease of the voltage level of internal node NB is determined by the capacitance value of capacitance element 41, the capacitance value of the parasitic capacitance of internal node NB and the voltage level of output power supply voltage VDDQ. If the capacitance value of capacitance element 41 is sufficiently greater than the capacitance value of the parasitic capacitance of internal node NB, even when internal node NB is precharged to output power supply voltage VDDQ level, internal node NB can be reliably driven to the negative voltage VBB level. In addition, the gate and source voltages of MOS transistor 43 are the same voltage level. Thus, even if node NB is driven to the negative voltage level, MOS transistor 43 can be surely maintained off.

When internal node NB is driven to negative voltage VBB level, P-channel MOS transistor PQ in output buffer circuit 5 drives output node 15b at high speed with a large driving power. On the other hand, the gate of P-channel MOS transistor PT receives a signal at ground voltage level from level conversion circuit 40 and output power supply voltage VDDQ is relatively low. Thus, P-channel MOS transistor PT supplies a current to output node 15b with a relatively small driving power.

MOS transistor PT, although being relatively small in driving power low, is provided for the following reason. Since MOS transistor 43 is turned off, internal node NB is in an electrically floating state. Therefore, even if the voltage level of internal node NB is lowered by the charge extracting operation of capacitance element 41, such a case can be possibly considered that the voltage level of the internal node NB is raised due to noise or leak current to reduce the driving power of P-channel MOS transistor PQ, failing to maintain the data bit DQ from the output node 15b at the output power supply voltage VDDQ level. In this state, therefore, MOS transistor PT is maintained conductive to maintain output node 15b at output power supply voltage VDDQ level. MOS transistor PT is thus provided for holding the voltage level of output node 15b and is not required to have a large driving capability, so that a signal at a ground voltage level is applied to the gate of MOS transistor PT.

When data read operation is completed, output permission signal OEM falls to L level, the output signal of NAND circuit 10 attains H level and the output signal of level conversion circuit 40 attains the output power supply voltage VDDQ level. Accordingly, MOS transistor 43 is turned on in response to the L level signal from inverter 42 and internal node NB is precharged to output power supply voltage VDDQ level again. Even if capacitance element 41 performs the charge pumping operation in response to the rise of the output signal of level conversion circuit 40, node NB is connected to output power supply node via MOS transistor 43 and the voltage level of node NB is at the output power supply voltage VDDQ level.

In the configuration of the output circuit shown in FIG. 7, a delay circuit may be arranged at a preceding stage of capacitance element 41, so as to allow the charge extracting operation of capacitance element 41 to start after MOS transistor 43 is turned off.

In addition, according to the configuration of the output circuit shown in FIG. 7, the output signal of level conversion circuit 40 is applied to capacitance element 41 and capacitance element 41 performs the charge pumping operation. Alternatively, if the capacitance value of capacitance element 41 can be set sufficiently greater than the capacitance value of the parasitic capacitance of internal node NB with a smaller occupying area by means of, for example, an MOS capacitor, the output signal of NAND circuit 10 may be applied to capacitance element 41 to effect the charge extracting operation on internal node NB in accordance with the output signal of NAND circuit 10.

[Modification]

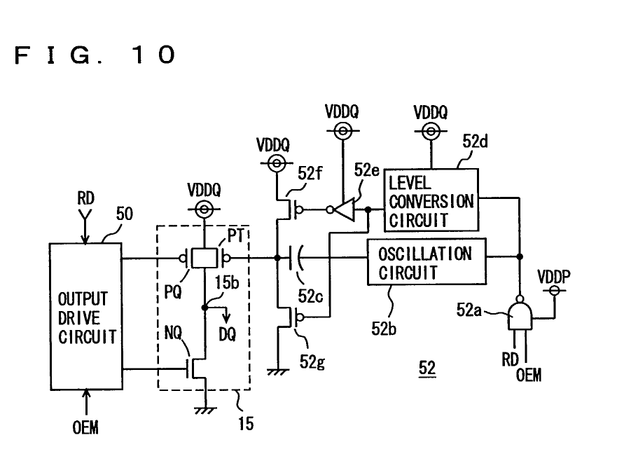

FIG. 9 is a block diagram of a modification of the third embodiment of the present invention. The configuration of an output circuit shown in FIG. 9 differs from that of the output circuit shown in FIG. 5 in the following points. In output buffer circuit 15 shown in FIG. 9, P-channel MOS transistor PT which receives, at a gate, the output signal of level conversion circuit 30 is provided in parallel to P-channel MOS transistor PQ.

The amplitude of the signal applied to the gate of P-channel MOS transistor PT is at output power supply voltage VDDQ level. When MOS transistor PT is conductive, a signal at ground voltage level is applied to the gate of transistor PT. Therefore, as in the case of the output circuit shown in FIG. 7, even if internal node NA is in a floating state at negative voltage level and has the voltage level unstable, an output node 15b can be reliably maintained at output power supply voltage VDDQ level.

As a result, even if output power supply voltage VDDQ is a low voltage, the output node 15b can be driven at high speed by MOS transistor PQ with the gate voltage thereof set at negative voltage level, and the pulled up data bit DQ can be reliably maintained at the output power supply voltage VDDQ level by MOS transistor PT.

As described above, according to the third embodiment of the present invention, the first pull-up transistor having a gate voltage driven to a negative voltage level and the second pull-up transistor having a gate driven to ground voltage level are provided as the transistors for pulling up in the output buffer circuit. Therefore, the first pull-up transistor can pull up the output node at high speed and the second transistor provided separately from the first pull-up transistor can ensure maintaining the output node pulled up to output power supply voltage level. Thus, output data bits can be generated at high speed.

[Fourth Embodiment]

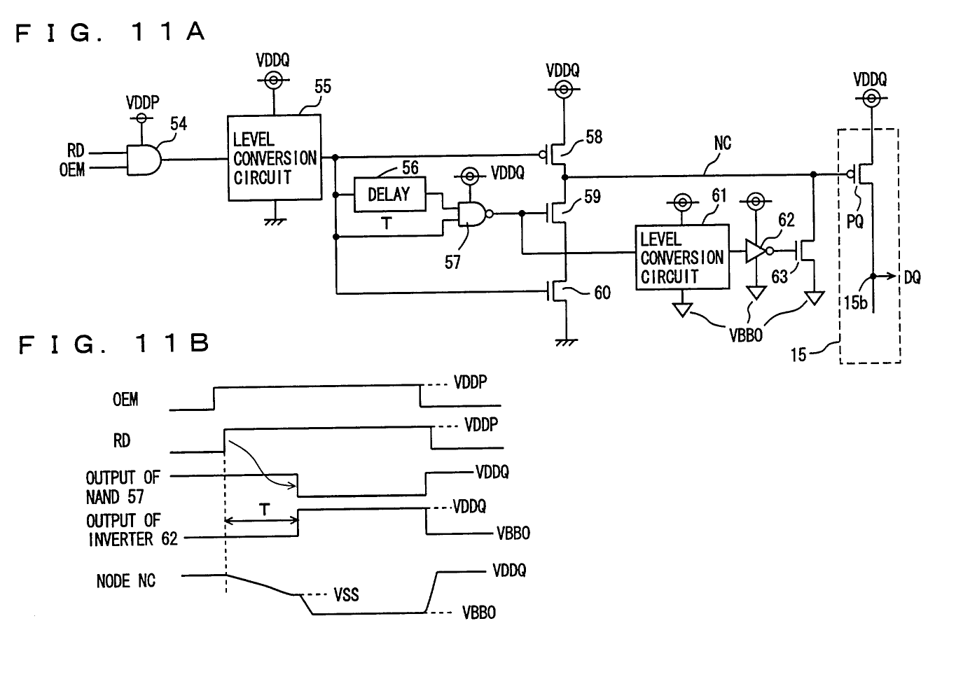

FIG. 10 is a schematic diagram showing a configuration of an output circuit of a fourth embodiment according to the present invention. In FIG. 10, in an output buffer circuit 15, P-channel MOS transistors PQ and PT for pulling up an output node are connected in parallel to each other between an output power supply node and an output node 15b.

MOS transistors PQ and NQ included in output buffer circuit 15 are driven by an output drive circuit 50. This output drive circuit 50 drives MOS transistors PQ and NQ in accordance with an internal read data RD and an output permission signal OEM. The configuration of output drive circuit 50 is the same as that of the driving section of output circuit shown in any of the preceding first to third embodiments. The L level of a signal applied to the gate of MOS transistor PQ is driven to a negative voltage level and the H level thereof is driven to an output power supply voltage VDDQ level. The H level of a signal applied to the gate of an N-channel MOS transistor NQ is driven to external a power supply voltage EXVDD level and the L level thereof is driven to ground voltage level.

A holding transistor drive circuit 52 is provided for voltage holding MOS transistor PT. Holding transistor drive circuit 52 includes a NAND circuit 52a which receives output permission signal OEM and internal read data RD, an oscillation circuit 52b which is activated when the output signal of NAND circuit 52a is at L level and performs oscillation operation at a predetermined cycle when activated, a level conversion circuit 52d which converts the amplitude of the output signal of NAND circuit 52a into output power supply voltage VDDQ level, an inverter 52e which inverts the output signal of level conversion circuit 52d, a P-channel MOS transistor 52f which turns conductive when the output signal of inverter 52e is at L level and charges the gate of MOS transistor PT to output power supply voltage VDDQ level when rendered conductive, a capacitance element 52c which performs a charge pumping operation in accordance with the output signal of oscillation circuit 52b to drive the gate potential of MOS transistor PT to a negative voltage level, and a clamping P-channel MOS transistor 52g which turns conductive when the output signal of level conversion circuit 52d is at L level to discharge the gate of MOS transistor PT.

NAND circuit 52a receives peripheral power supply voltage VDDP as one operating power supply voltage. Level conversion circuit 52d converts the H level signal of NAND circuit 52a into a signal at output power supply voltage VDDQ level. Inverter 52e receives output power supply voltage VDDQ as one operating power supply voltage.

The operating power supply voltage of oscillation circuit 52 may be peripheral power supply voltage VDDP, external power supply voltage EXVDD or output power supply voltage VDDQ. The operation of the output circuit shown in FIG. 10 will now be described.

The operation of output drive circuit 50 is the same as the operation of the output circuit shown in the preceding first to third embodiments and the gate of MOS transistor PQ is driven to the negative voltage level when made conductive.

In a standby state, the output signal of NAND circuit 52a is at H level and oscillation circuit 52b stops an oscillation operation. For the configuration of oscillation circuit 52 which stops the oscillation operation when the output signal of NAND circuit 52a is at H level, the following configuration can be utilized. An NOR circuit receiving, at a first input, the output signal of NAND circuit 52a and inverters of an even number of stages are connected in a ring form.

In the standby state, therefore, level conversion circuit 52d outputs an H level signal, MOS transistor 52g is turned off, MOS transistor 52f is turned on, the gate of MOS transistor PT is maintained at output power supply voltage VDDQ level and MOS transistor PT is maintained off.

When data read operation starts and the output signal of NAND circuit 52a attains L level, the output signal of level conversion circuit 52d attains L level and the gate of MOS transistor 52g is driven to ground voltage level. In addition, the output signal of inverter 52e attains output power supply voltage VDDQ level and MOS transistor 52f is turned off. As a result, the gate of MOS transistor PT is discharged to a voltage Vthp level by MOS transistor 52g Here, the voltage Vthp indicates the absolute value of the threshold voltage of MOS transistor 52g. Thereafter, oscillation circuit 52b performs an oscillation operation and the voltage level of the gate of MOS transistor PT is lowered by capacitance element 52c. When the gate voltage of MOS transistor PT is lowered down to the negative voltage level, the gate and source voltages of MOS transistor 52g attain ground voltage level and MOS transistor 52g is maintained off.

On the other hand, when the output signal of oscillation circuit 52b rises to H level, the voltage level of the gate of MOS transistor PT rises through the charge injection operation of capacitance element 52c. When the gate voltage of MOS transistor PT rises, MOS transistor 52g turns conductive and the voltage level of the gate of MOS transistor PT is clamped at the voltage Vthp. The output signal of gate voltage of MOS transistor PT, therefore, changes between the voltage Vthp and a voltage Vthp−VDD, provided that operating power supply voltage of oscillation circuit 52b is VDD and the amplitude of the output signal thereof is VDD.

As a result, in output drive circuit 50, even if the node which supplies a negative voltage to the gate of MOS transistor PQ is in an electrically floating state and the voltage level thereof is unstable, it is possible to maintain the voltage level of the output node 15b at the output power supply voltage VDDQ level by driving the gate potential of MOS transistor PT to negative voltage level at a predetermined period to ensure turning on of MOS transistor PT.

Further, since the gate voltage of voltage holding MOS transistor PT is intermittently driven to the negative voltage level at the oscillation period of oscillation circuit 52b, the transistor PT can assist MOS transistor PQ in the pull-up operation and output node 15b can be pulled up at high speed. Furthermore, since MOS transistor PT simply, intermittently assists in the pull-up operation, it is possible to prevent output node 15b from being driven at unnecessarily high speed, to thereby prevent the occurrence of ringing at output node 15b.

Since oscillation circuit 52b is simply required to drive the gate voltage of MOS transistor PT to the negative voltage level, it is possible to sufficiently decrease an area occupied by capacitance element 52c and oscillation circuit 52b and to decrease current consumption as well.

Moreover, since MOS transistor 52f is simply required to maintain the gate of MOS transistor PT at output power supply voltage VDDQ level when conductive, it is possible to make the size of transistor 52f sufficiently small.

Alternatively, the output circuit in this embodiment may be constituted such that the output signal of NAND circuit 52a is carried through the delay circuit to generate an oscillation operation activation signal for causing oscillation circuit 52b to perform the oscillation operation, in order to ensure that the oscillation operation is performed after the gate of voltage holding MOS transistor PT turns into a floating state.

As described above, according to the fourth embodiment of the present invention, the gate of the transistor for holding the voltage of the output node is held to negative voltage level by the charge pumping circuit, allowing an intermittent output node voltage holding operation. Even if the gate node of MOS transistor turns into a floating state, it is possible to reliably pull up and maintain the output node to the output power supply voltage level. In addition, even if this output drive circuit drives the gate of output pull-up MOS transistor PQ to a negative voltage level, it is possible to pull up the output node to the output power supply voltage level without generating ringing at the output node by intermittently driving the voltage holding MOS transistor PT into a conductive state.

[Fifth Embodiment]

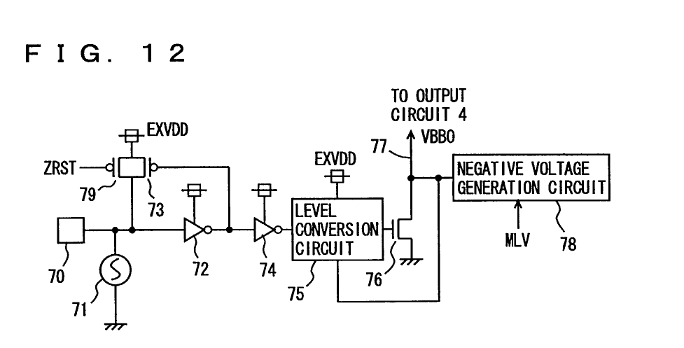

FIG. 11A is a diagram showing a construction of a main portion of an output circuit of a fifth embodiment according to the present invention. In FIG. 11A, the configuration of the section for driving pull-up P-channel MOS transistor PQ included in output buffer circuit 15 is shown. The section for driving the pull-down N-channel MOS transistor included in output buffer circuit 15 is comprised of gate circuit 11, level conversion circuit 13 and inverter 14 as in the case of any of the preceding first to fourth embodiments.

In FIG. 11A, the output circuit includes an AND circuit 54 which receives internal read data RD and output permission signal OEM, a level conversion circuit 55 which converts a signal having an amplitude of VDDP from AND circuit 54 into a signal having an amplitude of VDDQ, a delay circuit 56 which delays the output signal of level conversion circuit 55 by a predetermined time T, an NAND circuit 57 which receives the output signal of delay circuit 56 and the output signal of level conversion circuit 55, a P-channel MOS transistor 58 which turns conductive when the output signal of level conversion circuit 55 is at L level and charges an internal node NC to output power supply voltage VDDQ level when conductive, and N-channel MOS transistors 59 and 60 which are connected in series between internal node NC and a ground node.

The output signal of NAND circuit 57 is applied to the gate of MOS transistor 59. The output signal of level conversion circuit 55 is applied to the gate of MOS transistor 60. MOS transistor 59 is provided to mitigate the drain electric field of MOS transistor 60 to prevent element characteristic from being deteriorated by the generation of hot carries, compared with a case where MOS transistor 60 is solely provided. However, if the voltage level of output power supply voltage VDDQ is lowered and there is little possibility that a high drain electric field is generated in MOS transistor 60, MOS transistor 59 may be omitted.

The output circuit also includes a level conversion circuit 61 which converts the L level of the output signal of NAND circuit 57 into negative voltage VBB0 level, an inverter 62 which receives the output signal of level conversion circuit 61, and an N-channel MOS transistor 63 which is rendered conductive when the output signal of inverter 62 is at H level and drives internal node NC to negative voltage NBB0 level when conductive. Internal node NC is connected to the gate of pull-up P-channel MOS transistor PQ included in output buffer circuit 5. Level conversion circuit 61 and inverter 62 each receive output power supply voltage VDDQ as one operating power supply voltage. The configuration of level conversion circuit 61 is the same as the configuration of second level conversion circuit 21 shown in FIG. 3.

FIG. 11B is a signal waveform diagram representing an operation of the output circuit shown in FIG. 11A in a case when H level data is outputted. The operation of the output circuit shown in FIG. 11A in a case when H level data is outputted will now be described with reference to FIG. 11B.

In a standby state, the output signal of AND circuit 54 is at L level since output permission signal OEM is at L level and the output signal of level conversion circuit 55 is at L level, accordingly. In this state, MOS transistor 60 is non-conductive, MOS transistor 58 is conductive, internal node NC is charged to output power supply voltage VDDQ level and pull-up P-channel MOS transistor PQ in output buffer circuit 15 is maintained off.

In addition, the output signal of NAND circuit 57 is at H level, the output signal of inverter 62 is at L level of negative voltage VBB0 level and MOS transistor 63 is maintained off.

If both output permission signal OEM and internal read data RD attain H level, the output signal of AND circuit 54 attains H level or peripheral power supply voltage VDDP level, and the output signal of level conversion circuit 55 attains output power supply voltage VDDQ level, accordingly. P-channel MOS transistor 58 is turned off, responsively. On the other hand, N-channel MOS transistor 60 is turned on. In the standby state, the output signal of level conversion circuit 55 is at L level. Thus, when the output signal of level conversion circuit 55 rises to output power supply voltage VDDQ level, the output signal of delay circuit 56 rises to output power supply voltage VDDQ level after the time T passes. During delay time T provided by delay circuit 56, therefore, the output signal of NAND circuit 57 is at H level and MOS transistor 59 is kept conductive, accordingly.

After the delay time T provided by delay circuit 56 passes, the output signal of NAND circuit 57 attains L level and MOS transistor 59 is turned off. During the delay time T provided by delay circuit 56, therefore, internal node NC is driven to ground voltage VSS (VSSQ) level by MOS transistors 59 and 60. When the voltage level of internal node NC is lowered, MOS transistor PQ in output buffer circuit 15 is turned on and output node 15b is pulled up.

While the output signal of NAND circuit 57 is at H level, the output signal of level conversion circuit 61 is at H level as well, and MOS transistor 63 is maintained off by inverter 62.

When the output signal of NAND circuit 57 attains L level, the output signal of level conversion circuit 61 attains L level, accordingly, MOS transistor 63 is turned on by inverter 62, and internal node NC is driven to negative voltage VBB0 level. As a result, pull-up P-channel MOS transistor PQ included in output buffer circuit 15 is set to a deep ON (conductive) state to supply a greater amount of current to output node 15b to pull up output node 15b to output power supply voltage VDDQ level at high speed.

When output permission signal OEM attains L level, the output signal of AND circuit 54 attains L level and the output signal of level conversion circuit 55 attains L level again. Even if MOS transistor 59 is turned on, MOS transistor 60 is turned off in accordance with the output signal of level conversion circuit 55. In addition, the output signal of inverter 62 is at L level and MOS transistor 63 is turned off. As a result, internal node NC is charged again to output power supply voltage VDDQ level by MOS transistor 58.

As shown in FIG. 11A, by constituting the output circuit such that internal node NC is first driven to ground voltage level and then driven to a negative voltage level, it is possible to reduce the quantity of charges absorbed by the negative voltage generation circuit to decrease the consumed current in the negative voltage generation circuit, compared with a case of driving internal node NC from output power supply voltage VDDQ level to negative voltage VBB0 level in one step.

Further, pull-up P-channel MOS transistor PQ is driven in two steps. While being conductive, P-channel MOS transistor PQ first charges output node 15b when the gate to source voltage thereof is at output power supply voltage VDDQ level, then the gate to source voltage Vgs thereof is set at VDDQ−VBB0 and output node 15b is charged at high speed with a large current driving power. Consequently, it is possible to drive output node 15b to output power supply voltage VDDQ level at high speed without generating ringing at output node 15b.

As described above, according to the fifth embodiment of the present invention, the pull-up transistor in the output buffer circuit has the gate potential is driven first to ground voltage level and then to the negative voltage level, using the negative voltage from the negative voltage generation circuit when rendered conductive. Therefore, the negative voltage generation circuit is simply required to drive the node at the ground voltage level to negative voltage level. It is, therefore, possible to reduce the current consumption of the negative voltage generation circuit.

[Sixth Embodiment]

Different interfaces may apply to semiconductor memory devices in some cases. For example, there are cases where as to output power supply voltage VDDQ, a 1.8V system interface is employed and an LVTTL interface is employed. If this LVTTL interface is employed, output power supply voltage VDDQ is not less than 2.5V (2.5 to 3.3V) which is higher than in the 1.8V system interface. In this case, in particular, there is no need to drive the gate of a pull-up P-channel MOS transistor in an output buffer circuit to a negative voltage level. Therefore, in accordance with the voltage level of this output power supply voltage VDDQ, the L level of the gate voltage of the pull-up transistor in the output buffer circuit is set either to a negative voltage level or to a ground voltage level.

FIG. 12 is a schematic diagram showing a configuration of a negative voltage generation section of the sixth embodiment according to the present invention. In FIG. 12, a negative voltage generation section includes a pad 70 having a voltage level selectively set according to the voltage level of output power supply voltage VDDQ to be used, a link element 71 which is connected between pad 70 and a ground node, an inverter 72 which receives the voltage of pad 70 as an input signal, a P-channel MOS transistor 73 which is rendered conductive when the output signal of inverter 72 is at L level to maintain the input of inverter 72 at external power supply voltage EXVDD level, an inverter 74 which receives the output signal of inverter 72, a level conversion circuit 75 which converts the level of the output signal of inverter 74, an N-channel MOS transistor 76 which selectively connects a negative voltage transmission line 77 to the ground node in accordance with the output signal MLV of level conversion circuit 75, a negative voltage generation circuit 78 which is selectively activated in accordance with the output signal of level conversion circuit 75 and generates a negative voltage VBB0 on negative voltage transmission line 77 when activated, and a P-channel MOS transistor 79 which is selectively rendered conductive in accordance with a reset signal ZRST and charges the input of inverter 72 to external power supply voltage EXVDD level when conductive. Negative voltage VBB0 on negative voltage transmission line 77 is coupled to the negative voltage node of the output circuit shown in the preceding first and fifth embodiments.

Level conversion circuit 75 receives the voltage of the output node of negative voltage generation circuit as a low-level operating power supply voltage thereof.

Link element 71 is, for example, a fuse element and fusible using an energy ray such as laser. Link element 71 is selectively blown off depending on whether the interface of this semiconductor memory device is the 1.8V system interface or the LVTTL interface using output power supply voltage VDDQ set not less than 2.5V.

When power is turned on or a system is reset, reset signal ZRST is set at L level for a predetermined period and pad 70 is precharged to external power supply voltage EXVDD level by MOS transistor 79. When link element 71 is non-blown, the charging voltage of MOS transistor 79 is discharged through link element 71, the input signal of inverter 72 attains L level, inverter 72 outputs an H level signal, P-channel MOS transistor 73 is turned off and the voltage of pad 70 is maintained at ground voltage level by link element 71. In this state, the output signal of inverter 74 is at L level, output signal MLV of negative voltage generation circuit 78 attains L level and MOS transistor 75 is turned off. Accordingly, negative voltage transmission line 77 is disconnected from the ground node.

When output signal MLV of level conversion circuit 75 is at L level, negative voltage generation circuit 78 is activated, generates negative voltage VBB0 at a predetermined voltage level through, for example, the charge pumping operation and transmits negative voltage VBB0 thus generated to negative voltage transmission line 77. Negative voltage VBB0 generated by negative voltage generation circuit 78 is used as the low-level operating power supply voltage of level conversion circuit 75. An L level signal outputted from level conversion circuit 75 is a signal at negative voltage VBB0 level to ensure that MOS transistor 76 is maintained off, and negative voltage VBB0 generated by negative voltage generation circuit 78 is transmitted to output circuit 4 reliably.

On the other hand, in a case when link element 71 is blown off, even when pad 70 is precharged to power supply voltage EXVDD level for a predetermined period in accordance with reset signal ZRST, the output signal of inverter 72 attains L level, MOS transistor 73 is turned on, the input signal of inverter 72 attains L level, the output signal of inverter 72 attains H level and MOS transistor 73 is maintained off. The output signal of inverter 74 attains H level, output signal MLV of level conversion circuit 75 attains H level or external power supply voltage EXVDD level, as well, MOS transistor 76 is turned on and negative voltage transmission line 77 is connected to the ground node.

When the output signal of level conversion circuit 75 is at H level, the negative voltage generation operation of negative voltage generation circuit 78 is stopped. The L level-side operating power supply voltage of level conversion circuit 75 is at the level of the voltage on negative voltage transmission line 77, i.e., ground voltage level. Even if the negative voltage generation operation of negative voltage generation circuit 78 is stopped, it is ensured that the L level-side power supply voltage of level conversion circuit 75 is maintained at ground voltage level and level conversion circuit 75 stably executes a level conversion operation.

As a configuration in which the negative voltage generation operation is stopped when output signal MLV of level conversion circuit 75 is at H level, such a configuration can be employed that for an oscillation circuit activating a charge pumping operation, an NOR circuit receiving, at a first input, output signal MLV of level conversion circuit 75 and inverters of an even number of stages are connected in a ring form. The output signal of the inverter in the final stage is applied to the second input of the NOR circuit.

In addition, when the negative voltage generation operation of negative voltage generation circuit 78 is stopped, the output node of negative voltage generation circuit 78 is set to a ground voltage in accordance with the ground voltage of negative voltage transmission line 77. In this case, when the negative voltage generation operation is stopped, negative voltage generation circuit 78 is set into an output high impedance state. In other words, a transfer gate at the output stage may be fixedly set in an off state.

Accordingly, when link element 71 is in a blown off state, the negative voltage generation operation of negative voltage generation circuit 78 is stopped and output data is pulled up with a driving power suited to the LVTTL interface. On the other hand, when link element 71 is not blown, output signal MLV of level conversion circuit 75 is at L level. Negative voltage generation circuit 78 operates and the voltage of negative voltage transmission line 77 attains the negative voltage VBB0 level. Thus, even if output power supply voltage VDDQ is low in the 1.8V system interface, it is possible to generate output data at high speed.

The relation between the blow/non-blow of the link element and the interface may be opposite to that described above. In addition, the negative voltage generation operation of negative voltage generation circuit may be selectively activated in accordance with the presence/absence of the bonding to a pad.

Moreover, a configuration in which negative voltage generation circuit 78 transmits the ground voltage to negative voltage transmission line 77 when inactivated may be used.

As described above, according to the sixth embodiment, the voltage level of the gate of the pull-up transistor in the output buffer circuit is adjusted in accordance with the output power supply voltage level of the interface to be used. Thus, the output node can be driven with an optimum driving power according to an operation environment to be used, to stably generate output data at high speed.

[Seventh Embodiment]

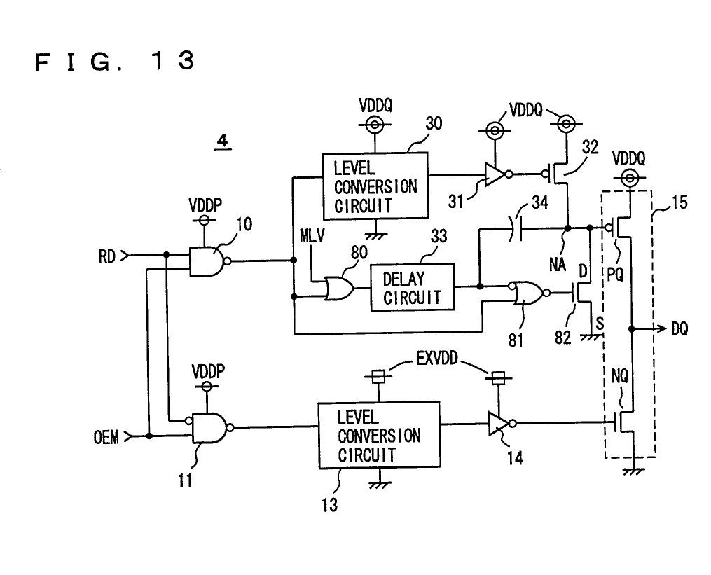

FIG. 13 is a schematic diagram showing a configuration of an output circuit of a seventh embodiment according to the present invention. The output circuit shown in FIG. 13 differs from the output circuit shown in FIG. 5 in the following points. In the output circuit shown in FIG. 13, a gate circuit 80 which receives a mode select signal MLV from level conversion circuit 75 shown in FIG. 12 and the output signal of NAND circuit 10, is provided in a front stage of delay circuit 33. In addition, a gate circuit 81 which receives the output signal of delay circuit 33 and the output signal of NAND circuit 10, and an N-channel MOS transistor 82 which drives an internal node NA to ground voltage level in accordance with the output signal of gate circuit 81 are arranged in place of gate circuit 35 and P-channel MOS transistor 36 shown in FIG. 5, respectively. Gate circuit 81 outputs an L level signal when the output signal of delay circuit 33 is at L level or the output signal of NAND circuit 10 is at H level.

The source and drain impurity regions of MOS transistor 82 are formed asymmetrically to each other, the source is connected to a ground node and the drain is connected to node NA.

Other configuration of the output circuit shown in FIG. 13 are the same as those of the output circuit shown in FIG. 5. Corresponding components are denoted by the same reference numerals as those in FIG. 5 and will not be described in detail.

Gate circuit 80 is an OR circuit. When mode select signal MLV is at H level, the output signal of gate circuit 80 is fixed to H level and the output signal of delay circuit 33 is fixed to H level, accordingly. When capacitance element 34 is constituted of an MOS capacitor, both the gate and source of capacitance element 34 are at H level, no channel region is formed and no MOS capacitance is formed. In addition, since the output signal of delay circuit 33 is fixed to H level, capacitance element 34 does not perform an operation for extracting charges from node NA.

On the other hand, gate circuit 81 operates as an inverter and the output signal of NAND circuit 10 is at L level, gate circuit 81 outputs an H level signal to maintain MOS transistor 82 conductive to drive internal node NA to ground voltage level. In this state, since the output signal of level conversion circuit 30 is at L level and the output signal of inverter 31 is at H level, MOS transistor 32 is turned off. As the voltage level of node NA is lowered, pull-up P-channel MOS transistor PQ is turned on. If this mode select signal MLV is at H level, an LVTTL mode is set and output power supply voltage VDDQ is at a voltage level not less than 2.5V. Even if the gate voltage of MOS transistor PQ is at ground voltage level, it is possible to drive the output node with a sufficiently large driving power.

On the other hand, if mode select signal is at L level, gate circuit 80 operates as a buffer circuit. As shown in FIG. 5, when the output signal of NAND circuit 10 is at L level, internal node NA is driven to negative voltage level through the capacitive coupling (charge pumping operation) of capacitance element 34 in response to the fall of the output signal of delay circuit 33.

Until node NA is driven down to negative voltage level, MOS transistor 82 is turned on to drive node NA to ground voltage level. Even if node NA is driven to negative voltage and the output signal of gate circuit 81 is at L level which is ground voltage level, the source of MOS transistor 82 is connected to the ground node, the gate voltage and the source voltage of MOS transistor 82 are equal to each other and MOS transistor 82 is maintained off. As a result, it is prevented that a current flows from the ground node in node NA to raise the negative voltage level of node NA.

Therefore, by selectively stopping the negative voltage generation operation in accordance with the power supply voltage level of the employed interface, it is possible to reliably, selectively activate a generation of a voltage according to this interface in an arrangement utilizing the charge injection operation or the charge pumping operation of a capacitance element. Thus, a driving power according to the voltage level of the output power supply voltage can be provided to the pull-up transistor of the output circuit.

If the absolute value of the voltage level of negative voltage VBB0 is smaller than the threshold voltage of MOS transistor 82, even when a negative voltage is generated on node NA, the gate to source voltage of MOS transistor 82 is lower than the threshold voltage thereof, and MOS transistor 82 is turned off. In this case, therefore, it is unnecessary to fixedly form the source and drain regions particularly.

[Modification]

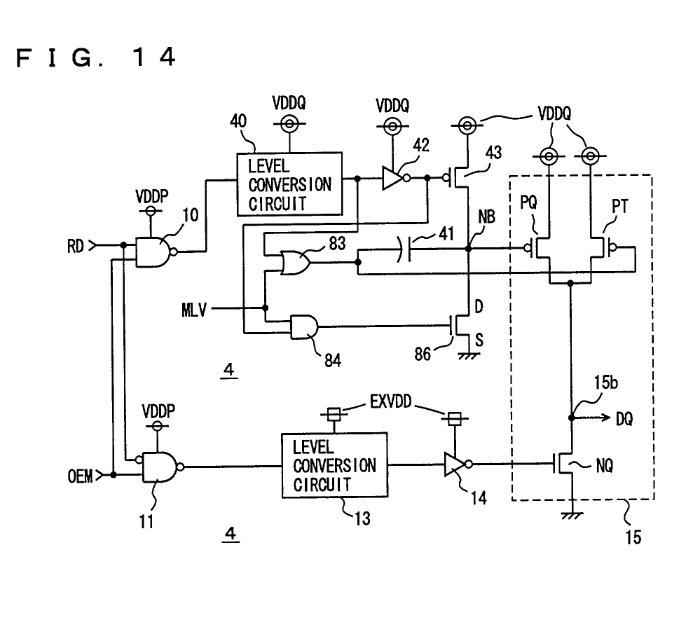

FIG. 14 is a schematic diagram showing a configuration of a modification of a seventh embodiment according to the present invention. Output circuit 4 shown in FIG. 14 differs in configuration from the output circuit shown in FIG. 7 in the following points. In output circuit 4 shown in FIG. 14, the output signal of an OR circuit 83 which receives mode select signal MLV and the output signal of level conversion circuit 40 is applied to capacitance element 41, and the output signal of OR circuit 83 is also applied to the gate of a voltage holding MOS transistor PT. Further, in output circuit 4 shown in FIG. 14, an AND circuit 84 which receives mode select signal MLV and the output signal of inverter circuit 42 and an N-channel MOS transistor 86 which connects internal node NB to a ground node in accordance with the output signal of AND circuit 84 are provided. MOS transistor 86 has the source and drain fixedly formed irrespectively of the voltage level of node NB, and the source connected to the ground node and the drain connected to node NB.

Other configuration of the output circuit shown in FIG. 14 is the same as that of the output circuit shown in FIG. 7. Corresponding components are denoted by the same reference numerals as those in FIG. 7, and will not be described in detail.

According to the configuration of the output circuit shown in FIG. 14, when mode select signal MLV is at H level, the output signal of OR circuit 83 is fixed to H level. In a case when capacitance element 41 is constituted of an MOS capacitor, no channel region is formed in capacitance element 41 and, therefore, capacitance element 41 does not function as a capacitance. In addition, MOS transistor PT is maintained off. On the other hand, the output signal of AND circuit 84 changes according to the output signal of inverter circuit 42 and MOS transistor 86 is turned on complementarily to MOS transistor 43. In this case, the voltage level of node NB changes between ground voltage level and output power supply voltage VDDQ level.

If mode select signal MLV is at L level, OR circuit 83 operates as a buffer circuit and performs a charge pullout operation and output node voltage holding operation as in the case of the output circuit shown in FIG. 7. The output signal of AND circuit 84 is fixed to L level, and MOS transistor 86 is maintained off, since the source of MOS transistor 86 is connected to the ground node. By fixing a drain region D and a source region S of MOS transistor 86, it is possible to ensure that MOS transistor 86 is maintained off even if internal node NB is driven to a negative voltage level.

Since capacitance element 41 is required to drive node NB from output power supply voltage VDDQ level to the negative voltage level, the capacitance value of capacitance element 41 is set sufficiently large. By using a MOS capacitor, it is possible to implement a capacitance element having a small area and a large capacitance value.

As for the construction of MOS transistor 86, for example, a substrate region (back gate) is connected to internal node NB, the well region thereof is surrounded by an N well biased to, for example, output power supply voltage VDDQ to isolate the region forming MOS transistor 86 from other elements. If the voltage level of internal node NB is lowered to the negative voltage level, this substrate region also attains the negative voltage level and the region between the source to substrate region turns into an inversely biased state to prevent generating a leakage current. In this configuration, even if the gate potential of MOS transistor 86 is at ground voltage level, the voltage level of the substrate region is lowered to the negative voltage level and a threshold voltage becomes larger by a back gate bias effect, achieving a deeper OFF (non-conductive) state. In addition, to fix this source region, the source region and the drain region are formed asymmetrically to each other and the impurity concentration of the source region is lowered, for example, to allow a depletion layer to spread more widely than at the drain region.

Alternatively, in the output circuit shown in FIGS. 13 and 14, the voltage level of the node which receives mode select signal MLV may be fixed to H level or L level according to the interface by means of a metal mask interconnection line, instead of the use of mode select signal MLV.

As described above, according to the seventh embodiment of the present invention, the negative voltage generation operation is selectively stopped according to the power supply voltage level of the interface to be used. Even if a negative voltage is generated using the charge injection operation of the capacitance element, it is possible to reliably stop the negative voltage generation operation without exerting an adverse affect on the configuration of the negative voltage generation. As a result, it is possible to generate output data with an optimum driving power according to the power supply voltage level of the interface.

[Eighth Embodiment]

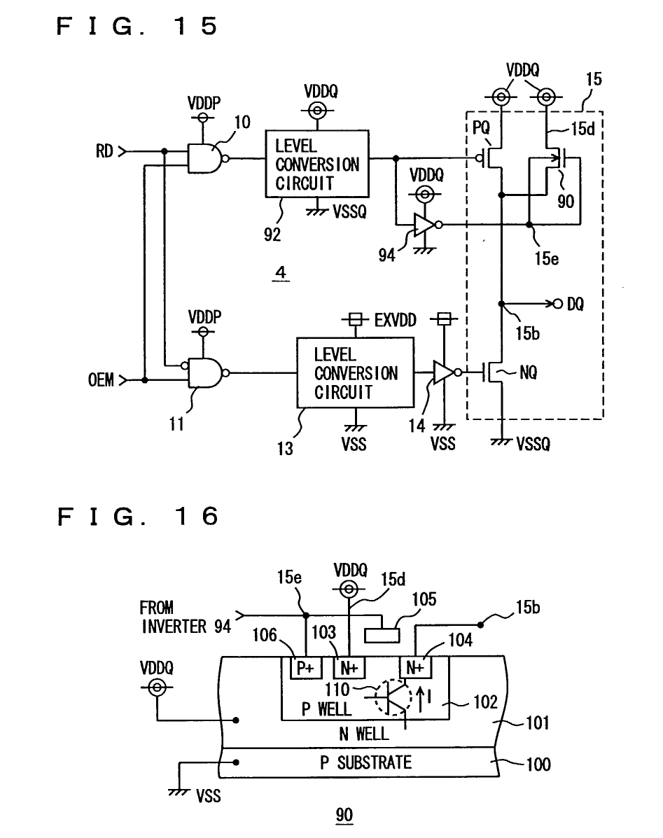

FIG. 15 is a schematic diagram showing a configuration of an output circuit of an eighth embodiment according to the present invention. In FIG. 15, an N-channel MOS transistor 90 is arranged in parallel to P-channel MOS transistor PQ for pulling up output node 15b in output buffer circuit 15. N-channel MOS transistor 90 has a back gate (substrate region) and a control gate set to the same voltage level. By setting the voltage levels of the gate and the back gate (substrate region) of N-channel MOS transistor 90 equal to each other, it is possible to eliminate a substrate bias effect, to drive MOS transistor 90 into an ON state at high speed and to increase the current driving capability of N-channel MOS transistor 90.

To drive MOS transistor 90, a level conversion circuit 92 which converts the amplitude of the output signal of NAND circuit 10 into the amplitude of a signal at output power supply voltage VDDQ level, and an inverter 94 which inverts the output signal of level conversion circuit 92 are provided. The output signal of level conversion circuit 92 is applied to the gate of pull-up P-channel MOS transistor PQ and the output signal of inverter 94 is applied to the back gate and control gate of N-channel MOS transistor 90. Inverter 94 receives output power supply voltage VDDQ as one operating power supply voltage.

The circuit section for driving pull-down N-channel MOS transistor NQ in output buffer circuit 15 is the same in configuration as that shown in FIG. 2. Corresponding components are denoted by the same reference numerals as those in FIG. 2 and will not be described in detail.

In the pull-up operation of output buffer circuit 15, the output signal of NAND circuit 10 is at L level and the output signal of gate circuit 11 is at H level. Therefore, the output signal of level conversion circuit 92 attains L level and the output signal of level conversion circuit 13 attains H level, whereby MOS transistor PQ is turned on and MOS transistor NQ is turned off by inverter 14. At this time, the output signal of inverter 94 is at H level or output power supply voltage VDDQ level and MOS transistor 90 is turned on. Therefore, output node 15b is driven by MOS transistors PQ and 90. Even if output power supply voltage VDDQ is at voltage level of, for example, 1.8V, MOS transistor 90 can compensate for a current driving power and output node 15b can be driven to output power supply voltage VDDQ level at high speed.

It is noted that by setting the voltage levels of the back gate and the control gate of MOS transistor 90 to be equal to each other, the current driving capability of MOS transistor 90 can be improved compared with a case of fixing the back gate to ground voltage level as will be described below.

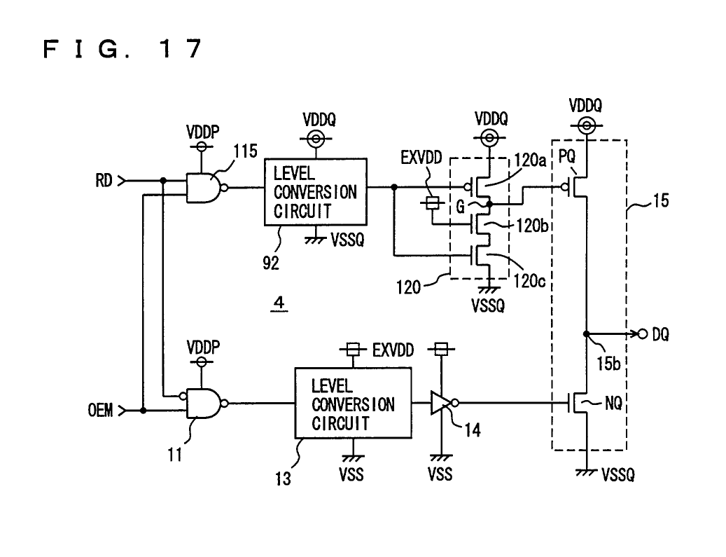

FIG. 16 is a schematic diagram of the cross-sectional structure of N-channel MOS transistor 90 shown in FIG. 15. In FIG. 16, MOS transistor 90 is formed in a P well 102 formed at the upper portion of an N well 101 biased to output power supply voltage VDDQ. N well 101 is formed on a P substrate (semiconductor substrate) 100 biased to ground voltage VSS level.

MOS transistor 90 includes N-type impurity regions 103 and 104 formed on the surface of P well 102 spaced away from each other, and a gate electrode 105 formed above P well 102 between impurity regions 103 and 104 with a not shown gate insulation film under-laid. P well 102 is connected to a node 15e through P-type impurity region 106 and gate electrode 105 is also connected to node 15e. An output signal from inverter 94 is transmitted to node 15e. Impurity region 103 receives output power supply voltage VDDQ through a power supply node 15d. Impurity region 104 is connected to output node 15b.

When the voltage of node 15e is at ground voltage level, P well 102 is biased to ground voltage level through impurity region 106. In this state, output node 15b is discharged to ground voltage level by pull-down N-channel MOS transistor NQ. Although P well 102 is equal in voltage level to impurity region 104, the PN junction between P well 102 and impurity region 104 are maintained in a nonconductive state due to the built-in voltage of this PN junction.

In addition, when output node 15b is in a high impedance state in a standby state, output node 15b is set to a bus terminating voltage level by the terminating resistance of an external bus to which output node 15b is connected. This terminating voltage is higher than a ground voltage. Even in the standby state, the PN junction between impurity region 104 and P well 102 is maintained nonconductive.

If the output signal of inverter 94 rises up to output power supply voltage VDDQ level, P well 102 is charged up to output power supply VDDQ level through impurity region 106. In this state, the voltage of gate electrode 105 rises to output power supply voltage VDDQ level, a channel is formed between impurity regions 103 and 104 and a current is supplied to output node 15b from power supply node 15d through this channel region. In addition, since P well 102 is biased to output power supply voltage VDDQ level, a parasitic NPN bipolar transistor 110 formed by N well 101, P well 102 and impurity region 104 is turned on and a current I is supplied to output node 15b from N well 101 through impurity region 104. Accordingly, by the supply of a current by N-channel MOS transistor 90 through the channel region and the injection of a current by the parasitic bipolar transistor, the voltage level of output node 15b can be raised at high speed.

In this case, since P well 102 is biased to output power supply voltage VDDQ level, P well 102 finally becomes equal in voltage level to impurity region 104 and the voltage levels of the back gate and the source of MOS transistor 90 become equal to each other. It is, therefore, possible to decrease a threshold voltage to increase the current driving power of N-channel MOS transistor without a substrate effect, thereby raising the voltage level of output node 15b at high speed.

N well 101 may be formed dedicatedly to MOS transistor 90. In addition, N well 101 may be provided for N-channel MOS transistors included in inverter 94 and level conversion circuit 92 shown in FIG. 15 in common. In this case, however, it is necessary to provide P well 102 for each N-channel MOS transistor.

As described above, according to the eighth embodiment of the present invention, the N-channel MOS transistor is provided in parallel to the pull-up P-channel MOS transistor in the output buffer circuit and the gate and the back gate of N-channel MOS transistor are fixed to the same voltage level. It is, therefore, possible to reduce the threshold voltage of N-channel MOS transistor, and even if output power supply voltage VDDQ is low, output node 15b can be charged with a large current driving power at high speed.

Furthermore, the P well region which forms the back gate of the assisting N-channel MOS transistor is formed in the N well biased to the output power supply voltage level. Therefore, while the pull-up N-channel MOS transistor is conductive, the lateral parasitic bipolar transistor can be kept conductive to supply a current from the N well to the output node to raise the output signal at high speed.

[Ninth Embodiment]

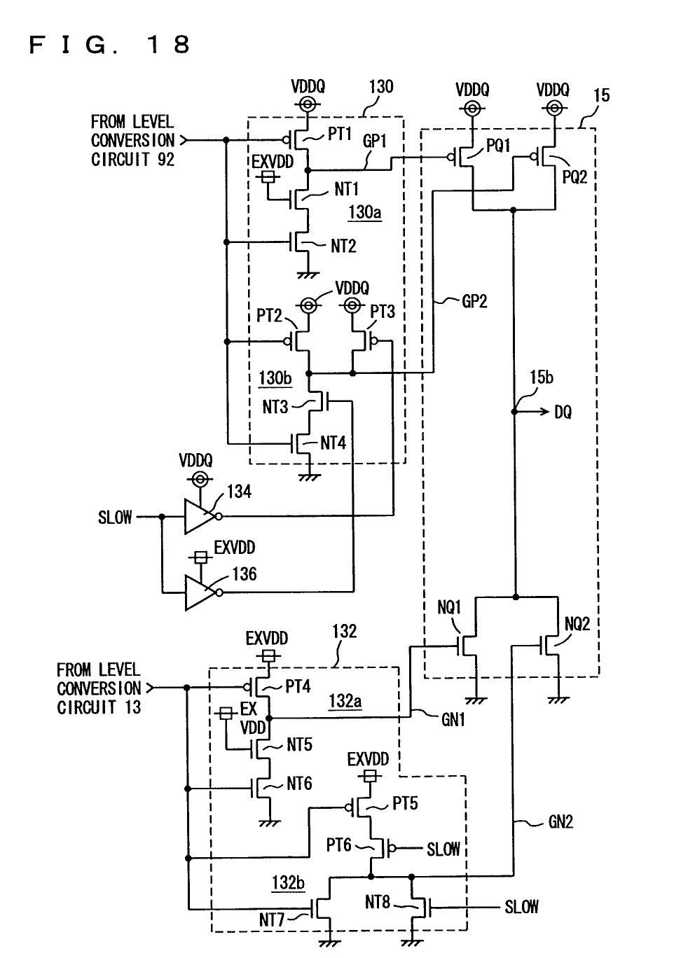

FIG. 17 is a schematic diagram showing a configuration of an output circuit of a ninth embodiment according to the present invention. In the output circuit shown in FIG. 17, there are provided an AND circuit 115 which receives internal read data RD and output permission signal OEM, level conversion circuit 92 which converts the level of the output signal of AND circuit 115, and a pull-up drive circuit 120 which drives pull-up P-channel MOS transistor PQ in output buffer circuit 15 in accordance with the output signal of level conversion circuit 92.

AND circuit 115 receives peripheral power supply voltage VDDP as an operating power supply voltage. Level conversion circuit 92 converts a signal having an amplitude of VDDP from AND circuit 115 into a signal having an amplitude of VDDQ while maintaining the logical level thereof.

Pull-up drive circuit 120 includes a P-channel MOS transistor 120a which is connected between an output power supply node and an internal node G and has a gate receiving the output signal of level conversion circuit 92, and N-channel MOS transistors 120b and 120c which are connected in series between internal node G and a ground node. Internal node G is connected to the gate of pull-up P-channel MOS transistor PQ in output buffer circuit 15.

N-channel MOS transistor 120b has a gate receiving external power supply voltage EXVDD and N-channel MOS transistor 120c has a gate receiving the output signal of level conversion circuit 92.

Output power supply voltage VDDQ is 1.8V or not less than 2.5V, depending on an input/output interface thereof. External power supply voltage EXVDD is fixed to 2.5V irrespectively of the interface to be used. N-channel MOS transistor 120b is provided for preventing the drain electric field of N-channel MOS transistor 120c from increasing to generate hot carriers when internal node G is charged up to output power supply voltage VDDQ level. That is, MOS transistors 120b and 120c divide the drain to source voltages of the respective transistors according to a channel resistance to reduce the drain electric field.

If output power supply voltage VDDQ is applied to the gate of MOS transistor 120b in the case of the 1.8V system interface, the gate voltage of N-channel MOS transistor 120b is low and the current driving power of MOS transistor 120b is low. Consequently, internal node G cannot be driven to ground voltage VSSQ level at high speed. Therefore, external power supply voltage EXVDD is applied to the gate of MOS transistor 120b to increase the current driving power of MOS transistor 120b to discharge internal node G to ground voltage VSSQ level at high speed, for driving pull-up MOS transistor PQ into a conductive state at high speed.

Even if output power supply voltage VDDQ is low, then the gate of pull-up P-channel MOS transistor PQ is discharged to ground voltage level at high speed, P-channel MOS transistor PQ is driven to be turned on at high speed and output node 15b is pulled up at high speed, accordingly.

The gate voltage of MOS transistor 120b may be selectively set at external power supply voltage EXVDD or output power supply voltage VDDQ according to the interface to be used. Specifically, the gate voltage of MOS transistor 120b may be set using mode select signal MLV (refer to the sixth embodiment). Further, by means of a metal mask interconnection line, the gate voltage of MOS transistor 120b may be set.

By using pull-up drive circuit 120, it is possible to drive the gate of pull-up P-channel MOS transistor PQ to ground voltage level at high speed and to drive pull-up P-channel MOS transistor PQ into a conductive state at high speed even if the output driving power of level conversion circuit 92 is low.

As described above, according to the ninth embodiment of the present invention, the gate voltage of the field mitigating MOS transistor in the pull-up transistor drive circuit is set at the external power supply voltage. Therefore, even if a power supply voltage is low, it is possible to turn pull-up P-channel MOS transistor PQ on at high speed to raise the output signal at high speed.

In the ninth embodiment, the configuration of the circuit section which drive pull-down MOS transistor NQ is the same as that in the first embodiment. The configuration of the circuit section in other embodiment, however, may be used.

[Tenth Embodiment]

FIG. 18 is a block diagram showing a configuration of a main portion of an output circuit of a tenth embodiment according to the present invention. In FIG. 18, two pull-up P-channel MOS transistors PQ1 and PQ2 and two pull-down N-channel MOS transistors NQ1 and NQ2 are provided in output buffer circuit 15. The output node driving capability of output buffer circuit 15 is set according to an operation mode instruction signal SLOW. If operating frequency is high or output load is heavy, all of MOS transistors PQ1, PQ2, NQ1 and NQ2 are enabled. If operating frequency is low or output load is light and it is not required to drive output node 15b at high speed, MOS transistors PQ1 and NQ1 are used.

In order to set the current driving capability of output buffer circuit 15, inverters 134 and 136 each receiving operation mode instruction signal SLOW stored in a not shown mode register are provided. Inverter 134 receives output power supply voltage VDDQ as one operating power supply voltage and inverter 136 receives external power supply voltage EXVDD as one operating power supply voltage.

A pull-up drive circuit 130 is provided to drive pull-up P-channel MOS transistors PQ1 and PQ2, and a pull-down drive circuit 132 is provided to drive pull-down N-channel MOS transistors NQ1 and NQ2. Pull-up drive circuit 130 includes a first drive circuit 130 which drives pull-up MOS transistor PQ1 in accordance with the output signal of level conversion circuit 92 shown in FIG. 18, and a second drive circuit 130b which is selectively activated in accordance with operation mode instruction signal SLOW and drives pull-up MOS transistor PQ2 in accordance with the output signal of level conversion circuit 92 when activated.

First drive circuit 130 includes a P-channel MOS transistor PT1 which is connected between an output power supply node and an internal node GP1 and has a gate receiving the output signal of level conversion circuit 92, and N-channel MOS transistors NT1 and NT2 which are connected in series between internal node GP1 and a ground node (VSSQ node). External power supply voltage EXVDD is applied to the gate of N-channel MOS transistor NT1 as in the case of MOS transistor 120b in the preceding ninth embodiment. The output signal of level conversion circuit 92 shown in FIG. 17 is applied to the gate of MOS transistor NT2. MOS transistor NT1 is provided to mitigate a drain electric field.

Second drive circuit 130b includes a P-channel MOS transistor PT2 which is connected between the output power supply node and an internal node GP2 and has a gate receiving the output signal of level conversion circuit 92, a P-channel MOS transistor PT3 which is connected between the output power supply node and internal node GP2 and has a gate receiving the output signal of an inverter 134, and N-channel MOS transistors NT3 and NT4 which are connected in series between internal node GP2 and the ground node (VSSQ node). The output signal of inverter 136 is applied to the gate of MOS transistor NT3 and the output signal of level conversion circuit 92 is applied to the gate of MOS transistor NT4.

Pull-down drive circuit 132 includes a first pull-down driver 132a which drives pull-down MOS transistor NQ1 in accordance with the output signal of level conversion circuit 13 shown in FIG. 17 and a second pull-down driver 132b which is selectively activated in accordance with operation mode instruction signal SLOW and drives pull-down MOS transistor NQ2 in accordance with the output signal of level conversion circuit 13 when activated.

First pull-down driver 132a includes a P-channel MOS transistor PT4 which is connected between an external power supply node and an internal node GN1 and has a gate receiving the output signal of level conversion circuit 13, and N-channel MOS transistors NT5 and NT6 which are connected in series between internal node GN1 and the ground node (VSSQ node). External power supply voltage EXVDD is applied to the gate of MOS transistor NT5 and the output signal of level conversion circuit 13 is applied to the gate of MOS transistor NT6.

Second pull-down driver 132b includes P-channel MOS transistors PT5 and PT6 which are connected in series between the external power supply node and an internal node GN2, an N-channel MOS transistor NT7 which is connected between internal node GN2 and the ground node and has a gate receiving the output signal of level conversion circuit 13, and an N-channel MOS transistor NT8 which is connected between internal node GN2 and the ground node and has a gate receiving operation mode instruction signal SLOW.

The output signal of level conversion signal 13 is applied to the gate of MOS transistor PT5 and operation mode instruction signal SLOW is applied to the gate of MOS transistor PT6.

When operation mode instruction signal SLOW is at L level, the output signals of both inverters 134 and 136 are at H level. In this state, MOS transistor PT3 receives, at the gate thereof, a signal of output power supply voltage VDDQ level and is turned off in second drive circuit 130b. On the other hand, MOS transistor NT3 receives, at the gate thereof, a signal of external power supply voltage EXVDD level and is turned on. Therefore, first and second drive circuits 130a and 130b drive MOS transistors PQ1 and PQ2 in accordance with the output signal of level conversion circuit 92, respectively. MOS transistor NT3 receives, at the gate thereof, external power supply voltage EXVDD and is sufficiently low in on-resistance as in the case of the preceding ninth embodiment, and can drive the gate of MOS transistor PQ2 to ground voltage level at high speed.

In addition, in pull-down drive circuit 132, MOS transistor PT6 is turned on and MOS transistor NT8 is turned off. Therefore, first and second pull-down drivers 132a and 132b operate in accordance with the output signal of level conversion circuit 13 shown, for example, in FIG. 13 and can drive MOS transistors NQ1 and NQ2, respectively. When operation mode instruction signal SLOW is at L level, output node 15b is pulled up by two MOS transistors PQ1 and PQ2 or pulled down by two N-channel MOS transistors NQ1 and NQ2 in accordance with internal read data.

On the other hand, when operation mode instruction signal SLOW is set at H level, the output signals of inverters 134 and 136 become L level. In second drive circuit 130b, P-channel MOS transistor PT3 is turned on and MOS transistor NT3 is turned off. Therefore, internal node GP2 is fixed to output power supply voltage VDDQ level and MOS transistor PQ2 of output buffer circuit 15 is fixed to an off state. As a result, MOS transistor PQ1 is driven in accordance with the output signal of first drive circuit 130a and output node 15b is pulled up by one MOS transistor PQ1.

In pull-down drive circuit 132, MOS transistor PT6 is turned off, MOS transistor NT8 is turned on and internal node GN2 is fixed to ground voltage level. Therefore, MOS transistor NQ2 is always turned off and output node 15b is pulled down by MOS transistor NQ1.

Even with a configuration in which the driving capability of output buffer circuit 15 is changed in accordance with the operation mode instruction signal SLOW, by providing inverter 134 which receives output power supply voltage VDDQ as an operating power supply voltage and inverter 136 which receives external power supply voltage EXVDD as an operating power supply voltage separately, and by applying operation mode instruction signal SLOW at external power supply voltage EXVDD level to MOS transistor NT3 for mitigating the high drain electric field of MOS transistor NT4 in second drive circuit 130b, it is possible to set the conductance of field mitigating MOS transistor NT3 to be sufficiently high and to drive internal node GP2 to ground voltage level at high speed even if output power supply voltage VDDQ is low.

If the voltage level of operation mode instruction signal SLOW applied to inverters 134 and 136 is peripheral power supply voltage level, the input logical threshold voltage of each of inverters 134 and 136 may be adjusted according to this peripheral power supply voltage VDD level. The adjustment of this input logical threshold voltage can be achieved by adjusting the size of the MOS transistors constituting each inverter (adjusting the size ratio).

In addition, if operation mode instruction signal SLOW is commonly used as the operation mode instruction signal applied to pull-down drive circuit 132, operation mode instruction signal SLOW is formed into a signal at external power supply voltage EXVDD level.

Further, each of inverters 134 and 136 may have a level conversion function. In this case, inverters 134 and 136 can individually convert the level of operation mode instruction signal SLOW having an amplitude of peripheral power supply voltage level.

In pull-down drive circuit 132, the H level of operation mode instruction signal SLOW applied to the gate of P-channel MOS transistor PT6 is set at external power supply voltage EXVDD level. Operation mode instruction signal SLOW applied to N-channel MOS transistor NT8 may be at peripheral power supply voltage level, output power supply voltage level or external power supply voltage level.

As already described above, this operation mode instruction signal SLOW is stored in a not shown register circuit in accordance with a mode register set command.

As described above, even if the output node driving capability is changed in accordance with an operation mode, the circuits are separately provided for setting the H level of this operation mode instruction signal to the output power supply voltage and the external power supply voltage, respectively, and the external power supply voltage is applied to the gate of the field mitigating MOS transistor for driving the pull-up MOS transistor. Thus, even if the output power supply voltage is altered, it is possible to turn the pull-up transistor on at high speed in the high slew rate for pulling up the output signal at high speed.

[Eleventh Embodiment]

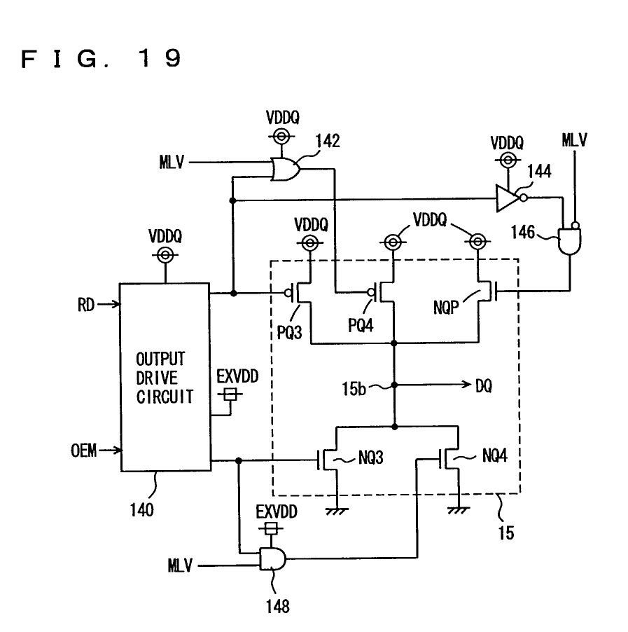

FIG. 19 is a schematic diagram showing a configuration of an output circuit of an eleventh embodiment according to the present invention. In FIG. 19, two P-channel MOS transistors PQ3 and PQ4 and one N-channel MOS transistor NQP are provided to pull up output node 15b in output buffer circuit 15. In addition, two N-channel MOS transistor NQ3 and NQ4 are provided to pull down output node 15b in output buffer circuit 15. On the pull-up side, MOS transistors PQ3, PQ4 and NQP are provided. When output power supply voltage VDDQ is set at 1.8V, the pull-up capability of the pull-up side is reduced. To compensate for the reduction of the pull-up capability, N-channel MOS transistor NQP is used to increase the driving capability as already described in the eighth embodiment. On the pull-down side, two N-channel MOS transistors NQ3 and NQ4 are provided. When the LVTTL interface is used and output power supply voltage VDDQ is set at 2.5V, for example, two MOS transistors NQ3 and NQ4 are used to discharge the voltage of output node 15b at high speed.

However, if output power supply voltage VDDQ is at LVTTL level and output node 15b is pulled up by MOS transistors PQ3 and PQ4 and NQP, the driving capability of the transistors becomes excessively high, ringing may possibly occur. In addition, the charging rate and discharging rate of output node 15b may possibly differ from each other. Thus, the number of MOS transistors used in output buffer circuit is adjusted according to the interface to be used.

P-channel MOS transistor PQ3 is always driven in accordance with the output signal of an output drive circuit 140. This output drive circuit 140 generates an output control signal in accordance with internal read data RD and output permission signal OEM. For the output control signal, a signal having an amplitude of output power supply voltage VDDQ level is generated for controlling the pull-up operation, and a signal having an amplitude of external power supply voltage EXVDD level is generated for controlling the pull-down operation (a circuit configuration for generating a negative voltage may be used in output drive circuit 140). Accordingly, this output drive circuit 140 uses output power supply voltage VDDQ for pull-up driving and uses external power supply voltage EXVDD for pull-down driving. The configuration of output drive circuit 140 may be any of the preceding first to tenth embodiments.

In order to control P-channel MOS transistor PQ4, an OR circuit 142 which receives the output signal of output drive circuit 140 and mode select signal MLV is provided. This OR circuit 142 receives output power supply voltage VDDQ as an operating power supply voltage. As shown in FIG. 12, the voltage level of mode select signal MLV is fixedly set in accordance with the 1.8V system interface or the LVTTL interface. This mode select signal MLV has an amplitude of not smaller than external power supply voltage EXVDD level. Since external power supply voltage EXVDD is not lower than output power supply voltage VDDQ, it is not particularly necessary to convert the level of mode select signal MLV.

In order to control N-channel MOS transistor NQP, there is provided an inverter 144 which receives the output control signal of output drive circuit 140 and a gate circuit 146 which receives the output signal of inverter 144 and mode select signal MLV. The output signal of gate circuit 146 is applied to MOS transistor NQP. As described in the preceding eighth embodiment with reference to FIG. 15, the output signal of gate circuit 146 may be applied to the gate and back gate of N-channel MOS transistor NQP. When mode select signal MLV is at L level, gate circuit 146 operates as a buffer circuit. When mode select signal MLV is at H level, gate circuit 146 outputs an L level signal fixedly.

Therefore, wen mode select signal MLV is set at H level and the LVTTL interface is designated, on the pull-up side, the output signal of OR circuit 142 attains H level and the output signal of gate circuit 146 attains L level, and MOS transistors PQ4 and NQP are turned off. As a result, output node 15b is driven by P-channel MOS transistor PQ3. In this case, output power supply voltage VDDQ is, for example, 2.5V, and MOS transistor PQ3 can drive output node 15b with a sufficiently large driving power.

On the other hand, when mode select signal MLV is set at L level, OR circuit 142 operates as a buffer circuit and gate circuit 146 also operates as a buffer circuit. In this case, therefore, MOS transistors PQ3, PQ4 and NQP operate in accordance with the output signal of output drive circuit 140. When mode select signal MLV is at L level, output power supply voltage VDDQ is, for example, 1.8V. By operating MOS transistors PQ3, PQ4 and NQP in parallel, the reduction of driving capability when the output power supply voltage is lowered, can be compensated for to pull up output node 15b at high speed.

On the pull-down side, N-channel MOS transistor NQ3 operates in accordance with the output control signal of output drive circuit 140. MOS transistor NQ4 operates in accordance with the output signal of an AND circuit 148 which receives the output control signal of output drive circuit 140 and mode select signal MLV. Therefore, when this mode select signal MLV is at H level, AND circuit 148 operates as a buffer circuit and MOS transistors NQ3 and NQ4 operate in parallel. When output mode 15b is driven in an amplitude of, for example, 2.5V level in the LVTTL mode, the H level voltage of output node 15b is discharged at high speed.

When mode select signal MLV is at L level, the output signal of AND circuit 148 is at L level and MOS transistor NQ4 is always turned off. In this state, output node 15b is driven by N-channel MOS transistor NQ3. When an H level signal is applied to the gate of MOS transistor NQ3, the gate voltage attains external power supply voltage EXVDD level and the H level signal of 1.8V at output node 15b can be driven to ground voltage level at high speed by one MOS transistor NQ3.

Accordingly, when mode select signal MLV is at H level and the LVTTL mode is designated and output power supply voltage is set at, for example, 2.5V, output node 15b is pulled up using P-channel MOS transistor PQ3 on the pull-up side. Output node 15b is also pulled down using N-channel MOS transistors NQ3 and NQ4 on the pull-down side in the LVTTL mode.

On the other hand, when mode select signal MLV is set at L level, output node 15b is pulled up using MOS transistors PQ3, PQ4 and NQP on the pull-up side and output node 15b is pulled down using MOS transistor NQ3 on the pull-down side.

By adjusting the capabilities for pulling-up and pulling-down output node 15b in accordance with the specification voltage level of the interface of output power supply voltage VDDQ, output node 15b can be pulled-up and pulled-down with the same characteristics and with an optimum driving capability in accordance with the output interface.

The gate voltage and size of each of MOS transistors PQ3, PQ4 and NQP are adjusted such that output node 15b can be driven at high speed under the condition of output power supply voltage VDDQ of 1.8V. The size of MOS transistor NQ3 is adjusted such that the voltage of 1.8V of output node 15b can be driven at high speed when external power supply voltage EXVDD is applied as a gate voltage thereof Accordingly, if the LVTTL interface is applied, the pull-down side cannot drive a signal having a larger amplitude at high speed and the driving capability of the pull-up side is excessively increased for the following reason. Under a low power supply voltage, the influence of the low power supply voltage on the source to gate voltage becomes larger on the pull-up side, and the pull-up side is mainly subject to application of a countermeasure against the lowering of the power supply voltage.

Furthermore, the configuration in which the output node driving capability is further adjusted in accordance with operation mode instruction signal SLOW shown in FIG. 18 may be used in the output circuit shown in FIG. 19. In this case, by using mode select signal MLV as operation mode instruction signal SLOW, it is possible to adjust a slew rate.

As described above, according to the eleventh embodiment of the present invention, the output node driving capability can be adjusted in accordance with the interface and the output node can be accurately pulled up and pulled down at high speed.

[Twelfth Embodiment]

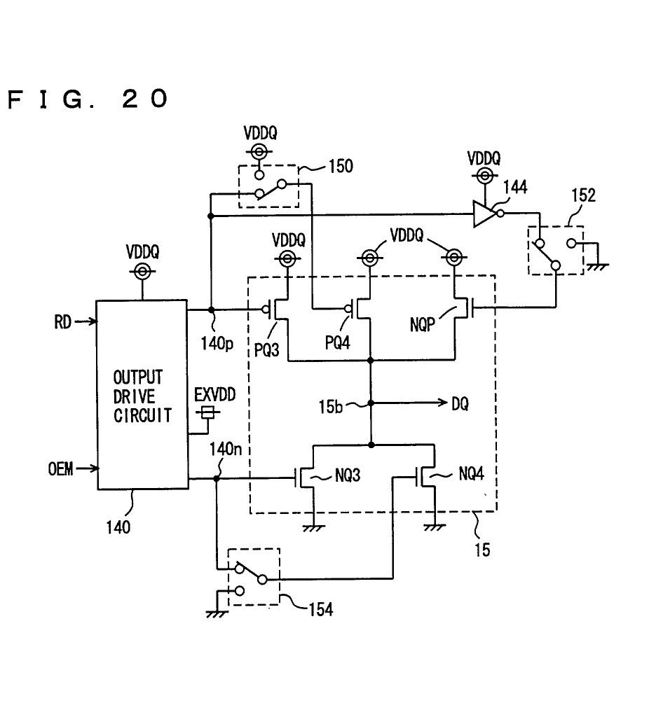

FIG. 20 is a schematic diagram showing a configuration of an output circuit according to a twelfth embodiment of the present invention. In the configuration of the output circuit shown in FIG. 20, the states of MOS transistors PQ4, NQP and NQ4 are set by metal switches 150, 152 and 154, respectively. The gate of MOS transistor PQ4 is electrically connected to one of an output power supply node and an output node 140p of output drive circuit 140 by metal switch 150. The gate of MOS transistor NQP is electrically connected to one of the output of inverter 144 and a ground node by metal switch 152. The gate of MOS transistor NQ4 is electrically connected to one of an output node 140n of output drive circuit 140 and the ground node by metal switch 153.

The connection paths of these metal switches 150, 152 and 154 are set by metal mask interconnection in a slice step or the like. Metal switches 150, 152 and 154 are used in place of OR circuit 142, gate circuit 146 and AND circuit 148 shown in FIG. 19, respectively.

In a semiconductor memory device, the bit width of output data DQ is, for example, ×16 bits or ×32 bits and this output data bit width is set in the slice step. Where the output bit width is set by such a master/slice scheme, it is a major trend to set output power supply voltage VDDQ to 3.3 V for output data bit width of ×32 bits, and to 1.8 V for the output data bit width of ×16 bits. Therefore, whether the output interface to be employed is the 1.8V interface or the LVTTL interface (VDDQ is 2.5 to 3.3V), is uniquely determined in accordance with the output data bit width. The output data bit width is switched by determining the output buffer circuit to be operable through the mask interconnection in the final slice step. In this slice step, the connection paths of metal switches 150, 152 and 154 shown in FIG. 20 are also set by metal mask interconnection. In FIG. 20, the connection paths of metal switches 150, 152 and 154 are shown for the output interface of the 1.8V interface.

According to the configuration shown in FIG. 20, it is not necessary to employ a mode select signal, and an occupation area and current consumption by the section for generating the mode select signal.

Likewise, as for the setting of connection paths of metal switch circuits, the connection paths of the metal switches are set in the slice step of setting the output data bit width. Therefore, there is no need to apply a dedicated process for the path setting, and the output buffer can be provided with the driving capability according to the output power supply voltage level without increasing the number of manufacturing steps.

[Thirteenth Embodiment]

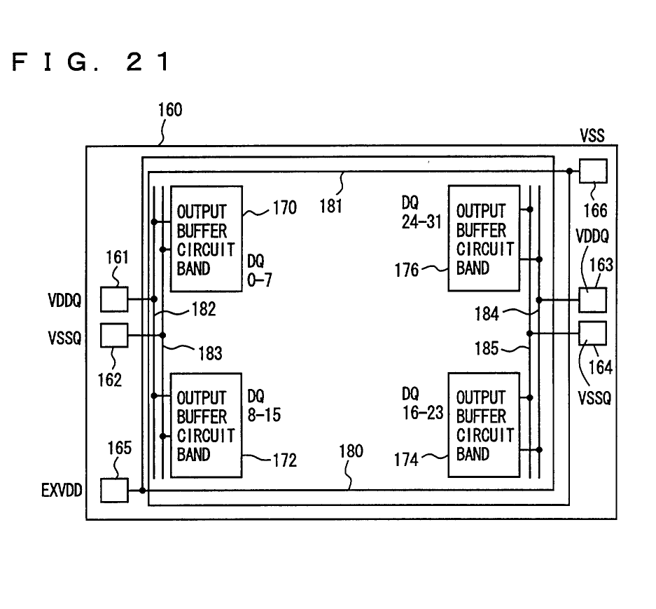

FIG. 21 shows an example of the arrangement of the power supplies and output circuitry of a semiconductor memory device according to a thirteenth embodiment of the present invention. In FIG. 21, output buffer circuits which outputs respective output data bits in the output circuit are arranged being divided into four output buffer circuit bands 170, 172, 173 and 176. Output buffer circuit band 170 includes output buffer circuits which output data bits DQ<7:0>, output buffer band 172 includes output buffer circuits which output data bits DQ<15:8>, output buffer band 174 includes output buffer circuits which output data bits DQ<23:16>, and output buffer band 176 includes output buffer circuits which output data bits DQ<31:24>. Output buffer bands 170 and 172 are arranged on one side of a semiconductor chip and output buffer bands 174 and 176 are arranged on the opposing other side of the semiconductor chip 160. If the output data bit width of this semiconductor memory device is switched between ×32 bits configuration and ×16 bits configuration in a master/slice step, output buffer circuits included in output buffer circuit bands 170 and 172 are used irrespectively of the output data bit width. Output data buffer circuits included in output buffer circuit bands 174 and 176 are used when the output data bit width is 32 bits, but not used when the output data bit width is 16 bits.

An output power supply pad 161 and an output ground pad 162 are arranged in correspondence to output buffer circuit bands 170 and 172. Output power supply voltage VDDQ applied to the output power supply pad 161 is transmitted to output buffer circuit bands 170 and 172 through an output power supply line 182. Output ground voltage VSSQ applied to output ground pad 162 is transmitted to output buffer circuit bands 170 and 172 through an output ground line 183. Output power supply line 182 and output ground line 183 are arranged corresponding to output buffer circuit bands 170 and 172.

An output power supply pad 163 and an output ground pad 164 are provided corresponding to output buffer circuit bands 174 and 176. Output power supply voltage VDDQ on output power supply pad 163 is transmitted to output buffer circuit bands 174 and 176 through an output power supply line 184. Output ground voltage VSSQ on output ground pad 164 is transmitted to output buffer circuit bands 174 and 176 through an output ground line 185. Output power supply line 184 and output ground line 185 are provided corresponding to output buffer circuit bands 174 and 176. That is, output power supply lines 182 and 184 are arranged separately from each other and output ground lines 183 and 185 are arranged separately from each other.

On the other hand, a power supply pad 165 and a ground pad 166 are arranged on semiconductor chip 160. External power supply voltage EXVDD on power supply pad 165 is transmitted over semiconductor chip 160 through an external power supply line 180. Ground voltage VSS on ground pad 166 is also transmitted over semiconductor chip 160 through a ground line 181. Power supply line 180 and ground line 181 are arranged over the entire semiconductor chip 160 along the periphery thereof so as to transmit external power supply voltage EXVDD and ground voltage VSS over the entire semiconductor chip 160. Alternatively, power supply line 180 and ground line 181 each may have opposing lines interconnected through branching lines to enhance the power sources. In other words, power supply line 181 and ground line 181 are arranged throughout semiconductor chip 160.

When the ×16 bit configuration is used in this semiconductor memory, no bonding wire is connected to pads 163 and 164 arranged for the ×32 bit configuration and the pads 163 and 164 are set in a floating state. In this sate, there is a possibility that each of output power supply line 184 and output ground line 185 enters a floating state, output buffer circuit bands 174 and 176 might malfunction due to noise on output power supply line 184 and output ground line 185, to exert an adverse influence on an internal circuit operation. In this case, since output power supply line 182 and output ground line 183 are arranged away from output power supply line 184 and output ground line 185, it is difficult to connect them. Accordingly, to stabilize the power supply nodes and ground nods when output buffer circuit bands 174 and 176 are not used, the following configuration is employed.

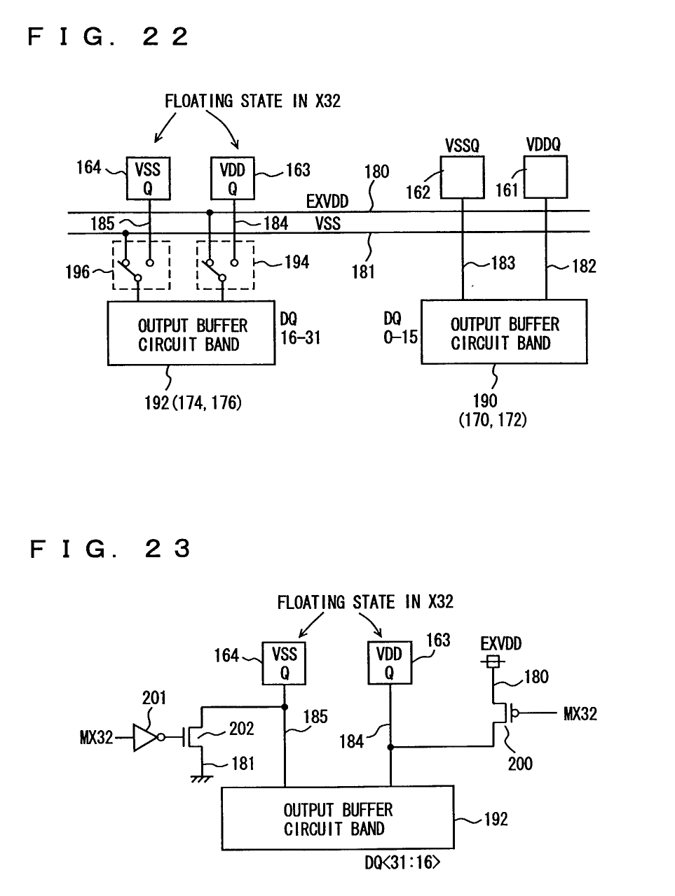

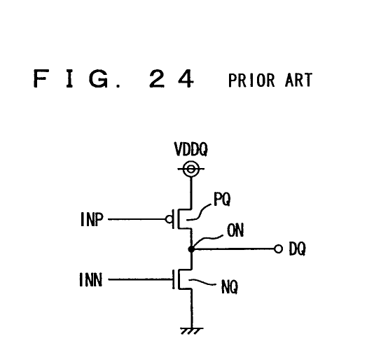

FIG. 22 shows the power supply arrangement for output buffer circuit bands 174 and 176 more specifically. In FIG. 22, for simplification of the drawing, output buffer circuit bands 170 and 172 provided for data bits DQ<15:0> are represented by one output buffer circuit band 190 and output buffer circuit bands 174 and 176 provided for data bits DQ<31:16> are represented by one output buffer circuit band 192.

Output buffer circuit band 190 is connected to output power supply pad 161 through output power supply line 182 and connected to output ground pad 162 through output ground line 183. Since output buffer circuit band 190 is used for both the output data bit widths of ×16 bit configuration and ×32 bit configuration, output buffer circuit band 190 is always connected to pads 161 and 162. Pads 161 and 162 are subject to bonding for both the output data bit widths of ×16 bit configuration and ×32 bit configuration, and are connected to external pin terminals.

Metal switches 194 and 196 are provided for output buffer circuit band 192. The connection path of metal switch 194 is determined by mask interconnection and metal switch 194 connects the power supply node of output buffer circuit band 192 to either output power supply pad 163 or power supply line 180. Likewise, metal switch 196 connects the ground node of output buffer circuit band 192 to either output ground pad 164 ground line 181 in accordance with the output data bit width. In FIG. 22, the connection paths of metal switches 194 and 196 in a case of the output data bit width of ×16 bits are shown. When the output data bit width is ×16 bits, pads 163 and 164 are not subject to bonding and are maintained in the floating state. In these state, metal switches 193 and 196 connect power supply line 180 and ground line 181 to power supply node and the ground node of output buffer circuit band 192, respectively. Even if output power supply line 182 and output ground line 183 for output buffer circuit band 190 are arranged far away from output power supply line 184 and output ground line 185 for output buffer circuit band 192 and it is difficult to interconnect these lines, it is possible to stabilize the voltage of the power supply node of output buffer circuit band 192 by connecting the power supply node and the ground node of output buffer circuit band 192 to power supply line 181 and ground line 181 transmitting external power supply voltage EXVDD and external ground voltage VSS, respectively. In a case of the ×16 bit configuration as the data bit width, the operation of output buffer circuit band 192 is prohibited by a not shown path. Thus, external power supply voltage EXVDD and ground voltage VSS are not consumed by output buffer circuit band 192, and no adverse influence is exerted on other circuits at all.

It is noted that the arrangement of the power supply pads and the ground pads is given only for illustrative purposes and any other arrangement of the power supply pads and the ground pads may be used. Likewise, the arrangement of the output buffer circuit bands is given only for illustrative purposes and any other arrangement may be used.

As described above, according to the thirteenth embodiment of the present invention, the power supply node and the ground node of a non-used output buffer circuit band are connected to the external power supply line and the external ground line, respectively. It is, therefore, possible to prevent the power supply node and the ground node of the non-used output buffer circuit band from entering a floating state, to prevent the non-used output buffer circuit band from malfunctioning due to the influence of noise or the like to adversely influence other circuit(s).

[Fourteenth Embodiment]

FIG. 23 is a schematic diagram showing a construction of a main portion of an output circuit according to a fourteenth embodiment of the present invention. In FIG. 23, the power supply arrangement for output buffer circuit band 192 outputting data bits DQ<31:16> is shown representatively. In FIG. 23, output power supply line 184 is electrically connected to external power supply line 180 through a P-channel MOS transistor 200 which is rendered conductive when a mode indication signal MX32 is at L level. Output ground line 185 is connected to ground line 181 through an MOS transistor 202 which is rendered conductive when the output signal of an inverter 201 receiving mode indication signal MX32 is at H level.

This mode indication signal MX32 is set at H level for ×32 bit configuration and set at L level for ×16 bit configuration. Therefore, when the output data bit width is 16 bits, MOS transistor 200 is turned on and output power supply line 184 is connected to the power supply pad through power supply line 180. In addition, MOS transistor 202 is turned on and output ground line 185 is connected to the ground pad through ground line 181. It is, therefore, possible to prevent output power supply line 184 and output ground line 185 from entering a floating state.

For the output data bit width of ×32 bit configuration, both MOS transistors 200 an 202 are turned off, output power supply line 184 is disconnected from power supply line 180 and output ground line 185 is disconnected from ground line 181. In this state, output power supply voltage VDDQ and output ground voltage VSSQ are applied through pads 163 and 164, respectively. Mode indication signal MX32 is generated by fixedly setting a specific pad voltage as shown in, for example, FIG. 12. Inverter 201 operates using external power supply voltage EXVDD as an operating power supply voltage. Therefore, since external power supply line 180 and ground line 181 are arranged extending over the semiconductor chip as shown in FIG. 21, MOS transistors 200 and 202 can be connected to external power supply line 180 and ground line 181, respectively. Further, in the configuration shown in FIG. 23, the data output bit width is changed between ×16 bits and ×32 bits. However, the data bit width may be changed between other bit widths, instead of 16 bits and 32 bits.

As described above, according to the fourteenth embodiment of the present invention, the power supply node and the ground node of the unused output buffer circuit are connected to the external power supply node and the ground node through the switching transistors, respectively. It is, therefore, possible to stabilize the power supply and the ground voltage of the output buffer circuit which is not used, with a simple circuit configuration.

In the first to fourteenth embodiments, the output circuit of the semiconductor memory device is described. However, the present invention is also applicable to any output circuit of which power supply voltage level is changed in accordance with an output interface.

As described so far, according to the present invention, the output circuit is so constituted as to adjust the driving capability of the output circuit in accordance with the voltage level of the output power supply voltage. It is, therefore, possible to drive the output node with an optimum driving capability in accordance with the output power supply voltage level and to stably, reliably generate an output signal at high speed.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An output circuit comprising:
a first transistor of a first conductive type connected between an output node and a power supply node supplying an output power supply, and made selectively conductive in accordance with an internal signal; and
a second transistor of a second conductive type connected between said power supply node and said output node, and made conductive in a common phase to said first transistor in accordance with said internal signal.

2. The output circuit according to claim 1, wherein
said second transistor comprises:
a well region of the first conducive type formed in a substrate region of the second conductive type, the substrate region biased to a level of said output power supply voltage;
first and second impurity regions of the second conductive type formed on a surface of said well region spaced away from each other; and
a gate electrode formed above the well region between said first and second impurity regions.

3. The output circuit according to claim 1, further comprising:
a drive circuit for driving said first transistor in accordance with said internal signal,
said drive circuit comprising third and fourth transistors of the second conductive type connected in series between a control electrode of said first transistor and a reference node supplying a voltage different in polarity from said output power supply voltage, the third transistor having a control electrode receiving an externally applied external power supply voltage, and said fourth transistor connected between said third transistor and said reference node and having a control electrode receiving a signal corresponding to said internal signal.

4. An output circuit comprising:
a first transistor of a first conductive type connected between an output power supply node and an output node;
a second transistor of the first conductive type connected between said output power supply node and said output node;
a first drive circuit for selectively driving said first transistor to a conductive state in accordance with an internal signal; and
a second drive circuit selectively activated in accordance with an operation mode instruction signal, and selectively driving said second transistor to the conductive state in accordance with said internal signal when activated,
said second drive circuit comprising;
a first gate circuit for generating a first control signal at a voltage level of said output power supply node in accordance with said operation mode instruction signal,
a second gate circuit for generating a second control signal at a level of an external power supply voltage in accordance with said operation mode instruction signal,
a third transistor for driving a gate electrode of said second transistor to a voltage level of said output power supply node in accordance with said internal signal,
a fourth transistor selectively rendered conductive in accordance with said first control signal, and driving a gate electrode of said second transistor to an output power supply voltage level of said output power supply node when rendered conductive, and
fifth and sixth transistors connected in series between the gate electrode of said second transistor and a reference node supplying a reference voltage different in polarity from said output power supply voltage, the fifth transistor receiving said second control signal at a gate electrode thereof, and the sixth transistor having a gate electrode receiving said internal signal.

5. The output circuit according to claim 4, wherein said first drive circuit comprises seventh and eighth transistors connected in series between a gate electrode of said first transistor and said reference node, the seventh transistor having a gate electrode receiving said external power supply voltage, and the eighth transistor being connected between said seventh transistor and said reference node, and having a gate electrode receiving said internal signal.

6. The output circuit according to claim 4, further comprising:
a seventh transistor connected between said output node and said reference node;
an eighth transistor connected between said output node and said reference node;
a third drive circuit for selectively driving said seventh transistor to a conductive state in accordance with said internal signal, said third drive circuit including ninth and tenth transistors connected in series between a gate electrode of said seventh transistor and said reference node, the ninth transistor having a gate electrode receiving said external power supply voltage, and the tenth transistor being connected between said ninth transistor and said reference node and having a gate electrode receiving a signal corresponding to said internal signal;
a fourth drive circuit for selectively driving said eighth transistor to a conductive state in accordance with said internal signal and said operation mode instruction signal, said fourth drive circuit including an eleventh transistor for driving the gate electrode of said eighth transistor to a level of said external power supply voltage in accordance with said operation mode instruction signal, a twelfth transistor for driving a gate electrode of said eighth transistor to a voltage level of said reference node in accordance with the signal corresponding to said internal signal, and a thirteenth transistor driving the gate electrode of said eighth transistor to the voltage level of said reference node in accordance with said operation mode instruction signal.

7. An output circuit comprising:
a first output stage having a driving capability fixedly and selectively settable in accordance with an operation mode specifying a level of a power supply voltage, and driving an output node to a voltage level of an output power supply node in accordance with an internal signal with a fixedly set driving capability.

8. The output circuit according to claim 7 further comprising:
a second output stage having a driving capability fixedly and selectively settable in accordance with said operation mode, and driving said output node to a voltage level of a reference node supplying a reference voltage different in polarity from said power supply voltage in accordance with said internal signal with a fixedly set driving capability.

9. The output circuit according to claim 7, wherein
said first output stage comprises:
a first transistor of a first conductive type for driving said output node to a level of said power supply voltage in accordance with said internal signal;
a second transistor of the first conductive type for driving said output node in accordance with an operation mode indication signal designating said operation mode and said internal signal; and
a third transistor of a second conductive type for driving said output node in accordance with said operation mode indication signal and an inverted signal of said internal signal.

10. The output circuit according to claim 7, wherein
said first output stage comprises:
a first transistor of a first conductive type for driving said output node to a level of said power supply voltage in accordance with said internal signal;
a second transistor of the first conductive type having a gate electrode fixedly and selectively connected to one of said power supply node and a transmission node transmitting said internal signal in accordance with said operation mode; and
a third transistor of a second conductive type set to one of an operation state of being responsive to an inverted signal of said internal signal and of a normally non-conductive state in accordance with said operation mode, and connected between said power supply node and said output node.

11. An output circuit comprising:
an output drive circuit for generating a signal changing between a negative voltage and an output power supply voltage in accordance with an internal signal; and
a first transistor driving an output node to a level of said output power supply voltage in accordance with an output signal of said output drive circuit.

12. The output circuit according to claim 11, wherein
said output drive circuit comprises a level conversion circuit for converting said internal signal into a signal changing between said output power supply voltage and said negative voltage.

13. The output circuit according to claim 11, wherein
said output drive circuit comprises:
a one-shot pulse signal generation circuit for generating a one-shot pulse signal in response to said internal signal;
a second transistor for driving a gate electrode of said first transistor to a voltage level of a reference node supplying a reference voltage different in polarity from said output power supply voltage in response to said one-shot pulse signal; and
a capacitance element for coupling a delayed signal of said internal signal to a gate electrode of said second transistor.

14. The output circuit according to claim 11 further comprising:
a second transistor for driving said output node to a level of said output power supply voltage in response to said internal signal.

15. The output circuit according to claim 11, wherein
said output drive circuit comprises a capacitance element causing a voltage change at a gate electrode of said first transistor through capacitive coupling in response to said internal signal.

16. The output circuit according to claim 11, further comprising:
a pump circuit for generating a second negative voltage through a charge pumping operation in accordance with said internal signal; and
a second transistor for holding said output node to a level of said output power supply voltage in accordance with an output voltage of said pump circuit.

17. The output circuit according to claim 11, wherein
said output control circuit comprises:
a pre-drive circuit for driving a gate electrode of said first transistor to a voltage level of a reference node supplying a reference voltage different in polarity from said output power supply voltage in accordance with said internal signal for a predetermined period; and
a driver for driving the gate electrode of said first transistor to a level of said negative voltage after said predetermined period passes.

18. An output circuit capable of changing a bit width of output data, comprising:
a plurality of data output circuits, arranged in correspondence to a maximum number of usable data output pads, each receiving an output power supply voltage applied to a corresponding output power supply node through an output power supply line as an operation power supply voltage for driving a corresponding pad in accordance with a corresponding internal signal when operating; and
switching circuitry for connecting the output power supply nodes of non-used data output circuits among said plurality of data output circuits to a power supply line different from said output power supply line in accordance with the bit width of said output data.

19. The output circuit according to claim 18, wherein
said switching circuitry comprises:
selection circuits, arranged corresponding to the data output circuits, each for fixedly connecting an output power supply node of a corresponding data output circuit to one of said output data power supply line and an external power supply line different from said output power supply line and transmitting an external voltage different from said output power supply voltage, in accordance with whether the corresponding data output circuit is non-used.

20. The output circuit according to claim 18, wherein
said plurality of data output circuits are divided into output circuit groups in a unit of a predetermined number of data output circuits;
said output power supply line is arranged in correspondence to each respective output circuit group; and
said switching circuitry comprises a switch circuit for connecting the output power supply line arranged corresponding to an output circuit group set to be non-used among said output circuit groups, to a node transmitting an external voltage different from the output power supply voltage transmitted by said output power supply line.
